(19) United States
(12) Patent Application Publication
(10) Pub. No.: US 2021/0388134 A1
(43) Pub. Date: Dec. 16, 2021

(54) CURABLE COMPOSITION FOR IMPRINTING, KIT, PATTERN PRODUCING METHOD, AND METHOD FOR MANUFACTURING SEMICONDUCTOR ELEMENT

(71) Applicant: FUJIFILM Corporation, Tokyo (JP)

(72) Inventors: Naoya SHIMOJU, Shizuoka (JP); Akinori SHIBUYA, Shizuoka (JP)

(73) Assignee: FUJIFILM Corporation, Tokyo (JP)

(21) Appl. No.: 17/412,239

(22) Filed: Aug. 25, 2021

Related U.S. Application Data
(63) Continuation of application No. PCT/JP2020/006667, filed on Feb. 20, 2020.

(30) Foreign Application Priority Data
Feb. 27, 2019 (JP) 2019-034371

(51) Int. Cl. C08F 212/08; C08F 222/10; C08F 2/50; C08F 220/06; C08G 61/10; G03F 7/00

(52) U.S. Cl. CPC C08F 212/08; C08F 222/102; C08F 2/50; C08L 71/02; C08G 61/10; G03F 7/0002; C08G 2261/1426; C08F 220/06

(57) ABSTRACT

Provided are: a curable composition for imprinting, which contains a compound C represented by Formula (C1) and a radical polymerization initiator; a kit including the curable composition; a pattern producing method using the curable composition; and a method for manufacturing a semiconductor element, which includes the pattern producing method as a step.

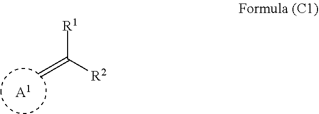

### CROSS-REFERENCE TO RELATED APPLICATIONS

This application is a Continuation of PCT International Application No. PCT/JP2020/006667 filed on Feb. 20, 2020, which claims priority under 35 U.S.C § 119(a) to Japanese Patent Application No. 2019-034371 filed on Feb. 27, 2019. Each of the above application(s) is hereby expressly incorporated by reference, in its entirety, into the present application.

### BACKGROUND OF THE INVENTION

### 1. Field of the Invention

The present invention relates to a curable composition for imprinting and a kit including the same. Moreover, the present invention relates to a pattern producing method using the curable composition, and a pattern obtained by the producing method. Furthermore, the present invention relates to a method for manufacturing a semiconductor element, which includes the pattern producing method as a step.

### 2. Description of the Related Art

An imprint method is a technique in which a fine pattern is transferred to a material by pressing a metal mold (generally called a mold or a stamper) on which a pattern is formed. The imprint method enables simple and precise production of a fine pattern, and thus is expected to be applied in various fields in recent years. In particular, a nanoimprint technique for forming a fine pattern of a nano-order level is attracting attention.

The imprint method is roughly classified into a thermal imprint method and an optical imprint method according to a transfer method thereof. In the thermal imprint method, a mold is pressed against a thermoplastic resin heated to a temperature equal to or higher than a glass transition temperature (hereinafter, referred to as a “Tg” in some cases), the thermoplastic resin is cooled, and then the mold is released to form a fine pattern. This method has an advantage that various materials can be selected, but also has problems in that a high pressure is required during pressing, and as the pattern size is finer, the dimensional accuracy is likely to be reduced due to thermal shrinkage or the like. Meanwhile, in the optical imprint method, after photocuring is performed in a state where a mold is pressed against a curable composition, the mold is released. In this method, high-pressure application or high-temperature heating is not required, a dimensional change before and after curing is small, and thus there is an advantage that a fine pattern can be formed with high accuracy.

In the optical imprint method, a curable composition for imprinting is applied onto a substrate, and then a mold made of a light-transmitting material such as quartz is pressed. The curable composition is cured by light irradiation in a state where the mold is pressed, and then the mold is released to produce a cured product (pattern) to which a desired pattern is transferred (for example, WO2016/047657A).

### SUMMARY OF THE INVENTION

As described above, the optical imprint method can be said to be a method suitable for forming a fine pattern, but even in such a method, as the pattern is made further finer in recent years, the problem of “pattern collapse” in which a pattern collapses in a case of releasing is apparent. As one of methods for improving releasability, for example, it is considered to add a release agent to a curable composition for imprinting. The addition of the release agent reduces an interaction between the curable composition and a mold in a case of releasing, and thus there is a possibility that an external force applied to the pattern in a case of releasing is reduced and the pattern collapse is suppressed.

However, a control range of an addition amount of the release agent is narrow, and depending on imprinting conditions (for example, a pattern size, a type of a material, or the like), even in a case where the release agent is added to the curable composition, pattern collapse is not sufficiently suppressed in some cases. Therefore, also from the viewpoint other than the addition of the release agent, any method is desirable as long as the method is a method capable of suppressing pattern collapse.

The present invention has been made in consideration of the aforementioned problems, and an object of the present invention is to provide a curable composition capable of suppressing pattern collapse by a method other than the addition of a release agent in an imprint method, and a kit.

Moreover, another object of the present invention is to provide a pattern producing method using the curable composition, and a pattern obtained by the producing method. Furthermore, still another object of the present invention is to provide a method for manufacturing a semiconductor element, which includes the pattern producing method as a step.

The aforementioned problems can be solved by adding a material, which is capable of increasing a modulus of elasticity of a curable composition after curing, to the curable composition. Specifically, the aforementioned problems can be solved by the following unit <1> and preferably by a unit <2> and subsequent units.

<1>

A curable composition for imprinting, comprising:

a compound C represented by Formula (C1); and

a radical polymerization initiator.

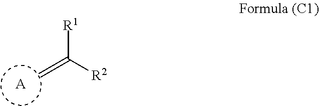

In Formula (C1), A¹ represents a ring structure having 4 to 20 ring members, and R¹ and R² each independently represent a hydrogen atom or a substituent, and

A¹ may have one or more substituents on the ring structure, and in a case where A¹ has a plurality of substituents, the respective substituents may be bonded to each other to form a ring.

<2>

The curable composition as described in <1>, in which the compound C includes a compound represented by Formula (C2).

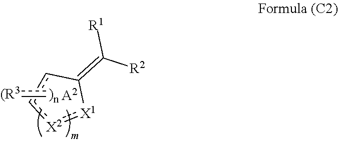

In Formula (C2), A² represents a ring structure having (m+4) ring members, R¹ and R² each independently represent a hydrogen atom or a substituent, R's each independently represent an oxygen atom, a sulfur atom, or a substituent, X¹ and X² each independently represent a carbon atom, a nitrogen atom, an oxygen atom, or a sulfur atom, m represents an integer of 0 to 3, n represents an integer of 0 to 12, the respective R³'s may be bonded to each other to form a ring, and a double line consisting of a solid line and a dotted line represents a single bond or a double bond.

<3>

The curable composition as described in <1>, in which the compound C includes a compound represented by Formula (C3).

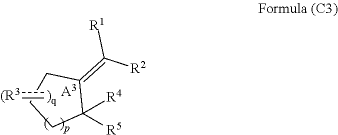

In Formula (C3), A³ represents a ring structure having (p+4) ring members, R¹, R², R⁴, and R⁵ each independently represent a hydrogen atom or a substituent, R³'s each independently represent an oxygen atom, a sulfur atom, or a substituent, p represents an integer of 0 to 3, q represents an integer of 0 to 12, R³, R⁴, and R⁵ may be bonded to each other to form a ring, and a double line consisting of a solid line and a dotted line represents a single bond or a double bond.

<4>

The curable composition as described in <3>, in which at least one of R⁴ or R⁵ is an alkyl group.

<5>

The curable composition as described in any one of <2> to <4>, in which at least two of R³'s in Formula (C2) or at least two of R³, R⁴, or R⁵ in Formula (C3) are bonded to each other to form a ring.

<6>

The curable composition as described in any one of <1> to <5>, in which at least one of R¹ or R² is a hydrogen atom.

<7>

The curable composition as described in any one of <1> to <6>, in which a content of the compound C is 0.01% to 10% by mass with respect to an amount of a total solid content.

<8>

The curable composition as described in any one of <1> to <7>, further comprising a polymerizable compound.

<9>

The curable composition as described in <8>, in which the polymerizable compound includes a polyfunctional polymerizable compound.

<10>

The curable composition as described in <8> or <9>, in which the polymerizable compound includes a polymerizable compound having an ethylenically unsaturated bond.

<11>

The curable composition as described in any one of <8> to <10>, in which a content of the compound C is 0.01% to 20% by mass with respect to the total polymerizable compound.

<12>

The curable composition as described in any one of <1> to <11>, in which the radical polymerization initiator includes a photoradical polymerization initiator.

<13>

The curable composition as described in any one of <1> to <12>, further comprising a release agent.

<14>

The curable composition as described in <13>, in which the release agent has a polyalkylene glycol structure.

<15>

The curable composition as described in any one of <1> to <14>, which is used for imprinting.

<16>

A kit comprising:

the curable composition as described in any one of <1> to <15>; and

a composition for forming an underlayer film, which is for forming an underlayer film for imprinting.

<17>

A pattern producing method comprising applying the curable composition as described in any one of <1> to <15> onto a substrate or a mold and irradiating the curable composition with light in a state of being sandwiched between the mold and the substrate.

<18>

A pattern produced by the producing method as described in <17>.

<19>

A method for manufacturing a semiconductor element, comprising the producing method as described in <17> as a step.

<20>

The method for manufacturing a semiconductor element as described in <19>, further comprising performing etching using a pattern as a mask.

With the curable composition for imprinting and the kit according to an aspect of the present invention, pattern collapse in a case of releasing can also be suppressed by a method other than the addition of a release agent. Moreover, with the pattern producing method using the curable composition according to the aspect of the present invention, a fine pattern can be efficiently obtained. Furthermore, with the pattern and the method for manufacturing a semiconductor element according to the aspect of the present invention, a semiconductor element can be efficiently obtained.

### BRIEF DESCRIPTION OF THE DRAWINGS

FIG. 1 is a conceptual diagram showing a ring structure which is derived from a compound C and directly bonded to a main chain of a polymer.

### DESCRIPTION OF THE PREFERRED EMBODIMENTS

Hereinafter, representative embodiments of the present invention will be described. Respective constituent elements will be described based on the representative embodiments for convenience, but the present invention is not limited to such embodiments.

In the present specification, a numerical range expressed using the term “to” means a range which includes the preceding and succeeding numerical values of “to” as a lower limit value and an upper limit value, respectively.

In the present specification, the term “step” is meant to include not only an independent step, but also a step which cannot be clearly distinguished from other steps as long as an intended action of the step is achieved.

In the description of a group (atomic group) in the present specification, in a case where the group is described without specifying whether the group is substituted or unsubstituted, the description means that the group includes both a group having no substituent and a group having a substituent. For example, in a case where a group is simply described as an “alkyl group”, the description means that the alkyl group includes both an alkyl group having no substituent (unsubstituted alkyl group) and an alkyl group having a substituent (substituted alkyl group). Moreover, in a case where a group is simply described as an “alkyl group”, the description means that the alkyl group may be chain-like or cyclic, and may be linear or branched in a case where the alkyl group is chain-like. The same also applies to other groups such as an “alkenyl group”, an “alkylene group”, and an “alkenylene group”.

In the present specification, “light” includes not only light having a wavelength in an ultraviolet, near-ultraviolet, far-ultraviolet, visible, or infrared range, or an electromagnetic wave but also radiation. Examples of the radiation include a microwave, an electron beam, an extreme ultraviolet ray (EUV), and an X-ray. Moreover, laser light such as a 248-nm excimer laser, a 193-nm excimer laser, and a 172-nm excimer laser can also be used. The light may be monochromatic light (single-wavelength light) passing through an optical filter, or may be light (composite light) including a plurality of wavelengths.

In the present specification, “(meth)acrylate” means both “acrylate” and “methacrylate” or either of them, “(meth)acryl” means both “acryl” and “methacryl” or either of them, and “(meth)acryloyl” means both “acryloyl” or “methacryloyl” or either of them.

In the present specification, a solid content in a composition means components other than the solvent, and a concentration (content) of the solid content in the composition is represented by the mass percentage of the components other than the solvent with respect to the total mass of the composition.

In the present specification, a physical property value is a value under conditions where a temperature is 23° C. and an atmospheric pressure is 101,325 Pa (1 atm), unless otherwise specified.

In the present specification, a weight-average molecular weight (Mw) and a number-average molecular weight (Mn) are each expressed as a value in terms of polystyrene according to gel permeation chromatography (GPC measurement), unless otherwise specified. The weight-average molecular weight (Mw) and the number-average molecular weight (Mn) can be determined, for example, by using HLC-8220 (manufactured by TOSOH CORPORATION), and, as columns, GUARD COLUMN HZ-L, TSKgel Super HZM-M, TSKgel Super HZ4000, TSKgel Super HZ3000, and TSKgel Super HZ2000 (manufactured by TOSOH CORPORATION). Moreover, the measurement is performed using tetrahydrofuran (THF) as an eluent, unless otherwise specified. Furthermore, for the detection in the GPC measurement, a detector of ultraviolet rays (UV rays) having a wavelength of 254 nm is used, unless otherwise specified.

In the present specification, “imprint” preferably refers to transfer of a pattern with a size of 1 nm to 10 mm, and more preferably refers to transfer of a pattern with a size of about 10 nm to 100 μm (nanoimprint).

In the present specification, regarding a positional relationship of respective layers constituting a laminate, in a case where there is a description of “upper” or “lower”, another layer may be on an upper side or a lower side of a reference layer among a plurality of layers of interest. That is, a third layer or element may be further interposed between the reference layer and the other layer, and the reference layer and the other layer are not necessary to be in contact with each other. Moreover, unless otherwise specified, in a case where a direction in which layers are stacked on a substrate is referred to as “upward” or there is a photosensitive layer, a direction from the substrate to the photosensitive layer is referred to as “upward”, and the opposite direction is referred to as “downward”. Furthermore, such setting of upward and downward directions is for convenience in the present specification, and in a practical aspect, the “upward” direction in the present specification may be different from a vertically upward direction.

[Curable Composition]

A curable composition for imprinting according to an embodiment of the present invention contains a compound C represented by Formula (C1) and a radical polymerization initiator.

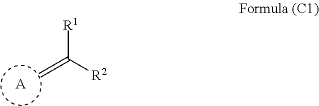

In Formula (C1), A¹ represents a ring structure having 4 to 20 ring members, and R¹ and R² each independently represent a hydrogen atom or a substituent, and

A¹ may have one or more substituents on the ring structure, and in a case where A¹ has a plurality of substituents, the respective substituents may be bonded to each other to form a ring.

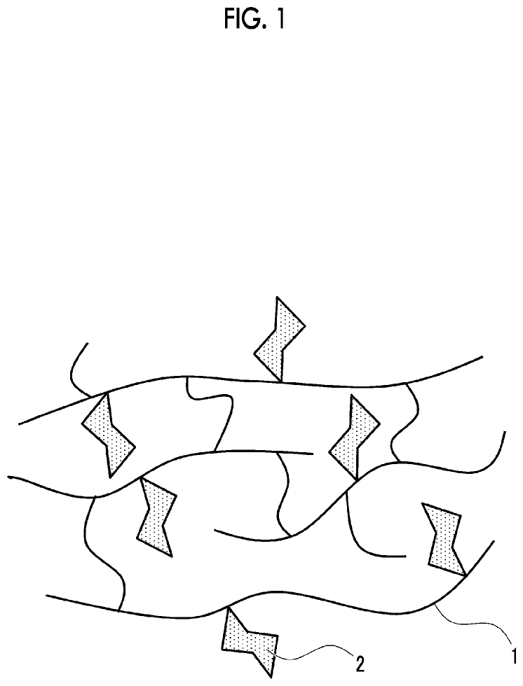

In the present invention, since the curable composition contains the compound C, pattern collapse can be suppressed in imprinting using radical polymerization, and then releasability of a mold is improved. It is considered that this is because, in a case where the curable composition is cured, an inter-carbon double bond directly bonded to the ring structure in the compound C is radically polymerized singly and/or with other compounds to form a structure in which a ring structure 2 derived from the compound C is directly bonded to a main chain 1 of a polymer, as shown in FIG. 1, that is, a structure in which the ring structure 2 and the main chain 1 of the polymer share one carbon atom. In a case where the main chain of the polymer can be considered to form a large network-like ring structure, such a polymer can be said to be a spiro compound in which two rings share the one carbon atom. In such a structure, the three-dimensional degree of freedom of the ring structure 2 is small, and the three-dimensional arrangement of the ring structure 2 with respect to the main chain 1 of the polymer is fixed. Furthermore, since such a ring structure 2 fills a gap between polymers, it is presumed that a modulus of elasticity of a cured product is improved, and as a result, it is presumed that durability of the cured product against an external force is improved, and pattern collapse in a case of releasing the mold is suppressed.

Hereinafter, each component of the curable composition according to the embodiment of the present invention will be described in detail.

<Compound C>

The compound C has a structure represented by Formula (C1). In particular, the compound C has an inter-carbon double bond directly bonded to a ring structure A¹. Moreover, even in a case where the compound C is recognized as having polymerizability, the compound C is not included in a “polymerizable compound” which will be described later in the present invention.

The ring structure A¹ may be any of an aliphatic ring, an aromatic ring, or a heterocycle (having both aromaticity and non-aromaticity), and is preferably an aliphatic ring or a non-aromatic heterocycle and more preferably an aliphatic ring. Here, the aliphatic ring is preferably cycloalkane or cycloalkene and more preferably cycloalkane. The non-aromatic heterocycle is preferably ethylene oxide, ethylene imine, and ethylene sulfide, which contain an oxygen atom, a nitrogen atom, and a sulfur atom (these atoms are collectively referred to as “heteroatoms”), respectively. The numbers of heteroatoms are each preferably 1 to 3, more preferably 1 or 2, and still more preferably 1.

The lower limit of the number of ring members (the number of atoms constituting the ring) in the ring structure A¹ is preferably 5 or more, and the upper limit of the number of ring members is preferably 15 or less, more preferably 10 or less, and still more preferably 7 or less. Moreover, the number of ring members in the ring structure A¹ is particularly preferably 6.

Specifically, the ring structure A¹ is preferably cycloalkane or cycloalkene having 4 to 10 carbon atoms, or ethylene oxide, ethylene imine, or ethylene sulfide having 4 to 10 ring members, more preferably cycloalkane or cycloalkene having 4 to 10 carbon atoms, or ethylene oxide having 4 to 10 ring members, still more preferably cycloalkane or cycloalkene having 4 to 10 carbon atoms, and particularly preferably cycloalkane having 4 to 10 carbon atoms. Moreover, the number of carbon atoms and the number of ring members are each preferably 5 to 8, more preferably 5 to 7, and still more preferably 5 or 6.

The substituent for R¹ and R² is preferably the following substituent T.

The substituent T is, for example, a halogen atom, a cyano group, a nitro group, a hydrocarbon group, a heteroaryl group, —ORₜ¹, —CORₜ¹, —COORₜ¹, —COORₜ¹, —NRₜ¹Rₜ², —NHCORₜ¹, —CONRₜ¹Rₜ², —NHCONRₜ¹Rₜ², —NHCOORₜ¹, —SRₜ¹, —SO₂Rₜ¹, —SO₂ORₜ¹, —NHSO₂Rₜ¹, or —SO₂NRₜ¹Rₜ². Rₜ¹ and Rₜ² each independently represent a hydrogen atom, a hydrocarbon group, or a heterocyclic group. Re and Rₜ² may be bonded to each other to form a ring.

Regarding the substituent T, examples of the halogen atom include a fluorine atom, a chlorine atom, a bromine atom, and an iodine atom. Examples of the hydrocarbon group include an alkyl group, an alkenyl group, an alkynyl group, and an aryl group. The number of carbon atoms in the alkyl group is preferably 1 to 10, more preferably 1 to 5, and still more preferably 1 or 2. The alkyl group may be linear, branched, or cyclic, and is preferably linear or branched and more preferably branched. The number of carbon atoms in the alkenyl group is preferably 2 to 10, more preferably 2 to 5, and particularly preferably 2 or 3. The alkenyl group may be linear, branched, or cyclic, and is preferably linear or branched. The number of carbon atoms in the alkynyl group is preferably 2 to 10 and more preferably 2 to 5. The alkynyl group may be linear, branched, or cyclic, and is preferably linear or branched. The number of carbon atoms in the aryl group is preferably 6 to 10, more preferably 6 to 8, and still more preferably 6 or 7. The heterocyclic group may be a single ring or a fused ring. The heterocyclic group is preferably a single ring or a fused ring having 2 to 4 fusion numbers. The number of heteroatoms constituting the ring of the heterocyclic group is preferably 1 to 3. The heteroatom constituting the ring of the heterocyclic group is preferably a nitrogen atom, an oxygen atom, or a sulfur atom. The number of carbon atoms constituting the ring of the heterocyclic group is preferably 3 to 10, more preferably 3 to 8, and still more preferably 3 to 5.

The hydrocarbon group and the heterocyclic group may further have a substituent or may be unsubstituted. Examples of the substituent here include the aforementioned substituents T.

The substituent for R¹ and R² is particularly preferably a halogen atom or a linear or branched alkyl group. Here, the halogen atom is preferably a fluorine atom, a chlorine atom, a bromine atom, or an iodine atom, more preferably a fluorine atom or a chlorine atom, and still more preferably a chlorine atom. The number of carbon atoms in the alkyl group is preferably 1 to 10, more preferably 1 to 5, and still more preferably 1 to 3. The upper limit of a formula weight of R¹ and R² is preferably 200 or less, more preferably 150 or less, still more preferably 100 or less, and particularly preferably 50 or less. Moreover, the lower limit of the formula weight of R¹ and R² is not particularly limited, but is, for example, 10 or greater.

More specifically, R¹ and R² are each preferably a hydrogen atom, a halogen atom, or a linear or branched alkyl group having 1 to 5 carbon atoms, more preferably a hydrogen atom, a fluorine atom, a chlorine atom, a methyl group, or an ethyl group, still more preferably a hydrogen atom or a methyl group, and particularly preferably a hydrogen atom. Moreover, it is preferable that at least one of R¹ or R² is a hydrogen atom, and more preferable that both of them are hydrogen atoms.

It is also preferable that the curable composition according to the embodiment of the present invention contains a compound represented by Formula (C2) as the compound C.

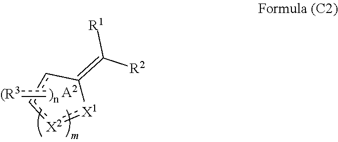

In Formula (C2), A² represents a ring structure having (m+4) ring members, R¹ and R² each independently represent a hydrogen atom or a substituent, R³'s each independently represent an oxygen atom, a sulfur atom, or a substituent, X¹ and X² each independently represent a carbon atom, a nitrogen atom, an oxygen atom, or a sulfur atom, m represents an integer of 0 to 3, n represents an integer of 0 to 12, the respective R³'s may be bonded to each other to form a ring, and a double line consisting of a solid line and a dotted line represents a single bond or a double bond.

A ring structure A² is preferably a single ring, but may be a polycyclic structure by bonding substituents to each other as will be described later. In a case where m is 0 to 3, the ring structures A² are each a 4-membered ring, a 5-membered ring, a 6-membered ring, or a 7-membered ring. In particular, it is preferable that m is 2, that is, the ring structure A² is a 6-membered ring. X¹ and X² are each independently preferably a carbon atom, a nitrogen atom, or an oxygen atom, more preferably a carbon atom or an oxygen atom, and still more preferably a carbon atom. Specific aspects that X¹ and X² can take are, for example, —CR¹⁰R¹¹—, —CR¹⁰═, NR¹⁰—, —N═, —O—, and —S—. Here, R¹⁰ and R¹¹ are each independently a hydrogen atom or R³ in Formula (C2).

n indicates the total number of atoms or substituents other than hydrogen atoms respectively bonded to the atoms (carbon atom, X¹, and X²) constituting the ring structure A². n is preferably 0 to 10, more preferably 0 to 6, and still more preferably 0 to 4. A bond connecting the ring structure A² and R³ may be a double bond, the number of double bonds is preferably 2 or less and more preferably 1 or less, and it is still more preferable that there are no double bonds. Furthermore, since R³ includes a hydrocarbon chain directly bonded to the ring structure A² by a double bond, in a case where the double bond (hereinafter, also referred to as “optional double bond”) of R³ and a double bond (that is, the double bond specified in Formula (C1), and hereinafter, also referred to as an “essential double bond”) of a carbon atom to which R¹ and R² are bonded cannot be clearly distinguished, any one of the double bonds is treated as an essential double bond, and the number of optional double bonds is counted. For example, in a compound C-18 illustrated below, there are two inter-carbon double bonds directly bonded to the ring structure, but one of them is treated as the essential double bond, and the number of optional double bonds is considered to be 1.

R¹ and R² have the same definitions as R¹ and R² in Formula (C1), respectively.

The substituent for R³ may be the same substituent as in the case of R¹ and R². In a case where R³ is an oxygen atom or a sulfur atom, a bond connecting R³ and the ring structure A² is a double bond. The upper limit of a formula weight of R³ is preferably 200 or less, more preferably 150 or less, still more preferably 100 or less, and particularly preferably 50 or less. Moreover, the lower limit of the formula weight of R³ is not particularly limited, but is, for example, 10 or greater.

The substituent for R³ is particularly preferably a halogen atom, a linear or branched alkyl group, a linear or branched alkenyl group, or a linear or branched alkylidene group. Here, the halogen atom is preferably a fluorine atom, a chlorine atom, a bromine atom, or an iodine atom, more preferably a fluorine atom or a chlorine atom, and still more preferably a chlorine atom. The number of carbon atoms in the alkyl group is preferably 1 to 10, more preferably 1 to 5, and still more preferably 1 to 3. The number of carbon atoms in the alkenyl group is preferably 2 to 10, more preferably 2 to 5, and still more preferably 2 or 3. The number of carbon atoms in the alkylidene group is preferably 1 to 10, more preferably 1 to 5, and still more preferably 1 to 3.

Specifically, R³ is preferably an oxygen atom (═O), a sulfur atom (═S), a linear or branched alkyl group having 1 to 5 carbon atoms (—C_{α}H_{2α+1}; α=1 to 5), a linear or branched alkenyl group having 2 to 5 carbon atoms (—C_{α}H_{2α-1}; α=2 to 5), or a linear or branched alkylidene group having 1 to 5 carbon atoms (═C_{α}H_{2α}; α=1 to 5). Moreover, R³ is more preferably an oxygen atom (═O), a sulfur atom (═S), a methyl group (—CH₃), an ethyl group (—C₂H₅), an ethenyl group (vinyl group, —C₂H₃), a methylidene group (═CH₂), or an ethylidene group (=C₂H₄), still more preferably an oxygen atom (═O), a sulfur atom (═S), or a methyl group (—CH₃), and particularly preferably a methyl group (—CH₃).

Furthermore, R³ can be bonded to another R³ in Formula (C2) to form a ring structure. In a case where R³ is bonded to another adjacent R³, the ring structure A² is a planar polycyclic structure. In a case where the ring structure A² is the planar polycyclic structure, the number of rings is preferably 2 to 5, more preferably 2 to 4, and still more preferably 2 or 3. Meanwhile, in a case where R³ is bonded to another R³ which is other than the adjacent R³, the ring structure A² is a three-dimensional polycyclic structure (structure in which crosslinking is formed in a molecule). In the present invention, from the viewpoint that the modulus of elasticity of the cured product is further improved, it is preferable that a three-dimensional polycyclic structure is formed as the ring structure A².

It is also preferable that the compound C further includes a compound represented by Formula (C3).

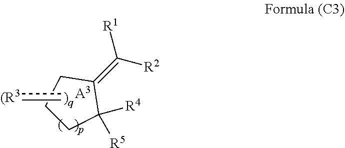

In Formula (C3), A³ represents a ring structure having (p+4) ring members, R¹, R², R⁴, and R⁵ each independently represent a hydrogen atom or a substituent, R³'s each independently represent an oxygen atom, a sulfur atom, or a substituent, p represents an integer of 0 to 3, q represents an integer of 0 to 12, R³, R⁴, and R⁵ may be bonded to each other to form a ring, and a double line consisting of a solid line and a dotted line represents a single bond or a double bond.

A ring structure A³ is preferably a single ring, but may be a polycyclic structure by bonding substituents to each other as will be described later. In a case where p is 0 to 3, the ring structures A³ are each a 4-membered ring, a 5-membered ring, a 6-membered ring, or a 7-membered ring. In particular, it is preferable that p is 2, that is, the ring structure A³ is a 6-membered ring. q indicates the total number of atoms or substituents other than hydrogen atoms respectively bonded to the carbon atoms constituting the ring structure A³. q is preferably 0 to 10, more preferably 0 to 6, and still more preferably 0 to 4.

R¹ and R² have the same definitions as R¹ and R² in Formula (C1), respectively.

R³ has the same definition as R³ in Formula (C2). Therefore, the substituent for R³ may be the same substituent as in the case of R¹ and R². In a case where R³ is an oxygen atom or a sulfur atom, a bond connecting R³ and the ring structure is a double bond.

In a case where at least one of R⁴ or R⁵ is a substituent, the substituent is particularly preferably a halogen atom, a linear or branched alkyl group, or a linear or branched alkenyl group. Here, the halogen atom is preferably a fluorine atom, a chlorine atom, a bromine atom, or an iodine atom, more preferably a fluorine atom or a chlorine atom, and still more preferably a chlorine atom. The number of carbon atoms in the alkyl group is preferably 1 to 10, more preferably 1 to 5, and still more preferably 1 to 3. The number of carbon atoms in the alkenyl group is preferably 2 to 10, more preferably 2 to 5, and still more preferably 2 or 3.

Specifically, R⁴ and R⁵ are each preferably a hydrogen atom, a linear or branched alkyl group having 1 to 5 carbon atoms, or a linear or branched alkenyl group having 2 to 5 carbon atoms, more preferably a hydrogen atom, a methyl group, an ethyl group, or an ethenyl group (vinyl group), and still more preferably a hydrogen atom or a methyl group. Moreover, it is preferable that at least one of R⁴ or R⁵ is an alkyl group, and more preferable that both of them are alkyl groups.

Furthermore, at least two of R³, R⁴, or R⁵ in Formula (C3) can be bonded to each other to form a ring structure, and here, the ring structure A³ may be a polycyclic structure. In this case, it is preferable that R³'s are bonded to each other. In a case where the ring structure A³ is the polycyclic structure, the number of rings is preferably 2 to 5, more preferably 2 to 4, and still more preferably 2 or 3. Moreover, as described above, R³ preferably forms a crosslinking structure in a molecule.

The molecular weight of the compound C is preferably 60 or greater and less than 2,000. The upper limit of the numerical range is more preferably 1,000 or less, still more preferably 500 or less, and particularly preferably 300 or less. The lower limit of the numerical range is more preferably 80 or greater, still more preferably 100 or greater, and particularly preferably 110 or greater. In a case where the content of the compound C with respect to the entire composition is within the above range, the effect of suppressing pattern collapse is further improved, and diffusibility of the compound C in the curable composition is also improved.

The content of the compound C in the curable composition is not particularly limited, but the content of the compound C is preferably 0.01% to 30% by mass with respect to an amount of a total solid content. The upper limit of the numerical range is more preferably 20% by mass or less, still more preferably 10% by mass or less, and particularly preferably 5% by mass or less. Moreover, the lower limit of the numerical range is more preferably 0.1% by mass or greater, still more preferably 0.5% by mass or greater, and particularly preferably 1.0% by mass or greater. In a case where the content of the compound C with respect to the entire composition is within the above range, the effect of suppressing pattern collapse is further improved. Furthermore, the content of the compound C is preferably 0.01% by mass or greater and less than 30% by mass with respect to the total polymerizable compound. The upper limit of the numerical range is more preferably 20% by mass or less, still more preferably 10% by mass or less, and particularly preferably 5% by mass or less. The lower limit of the numerical range is more preferably 0.1% by mass or greater, still more preferably 0.5% by mass or greater, and particularly preferably 1.0% by mass or greater. In a case where the content of the compound C with respect to the total polymerizable compound is within the above range, the effect of suppressing pattern collapse is further improved. Meanwhile, in the present invention, in a case where the curable composition does not contain the polymerizable compound, the content of the compound C in the curable composition is preferably 90% to 99% by mass, more preferably 93% to 97% by mass, and still more preferably 94% to 96% by mass.

One kind of the compounds C may be used singly, or two or more kinds thereof may be used in combination. In a case where two or more kinds of the compounds C are used in combination, it is preferable that the total content of the compounds C is within the above range.

Specific examples of the compound C are as follows. However, in the present invention, the compound C is not limited to compounds shown below.

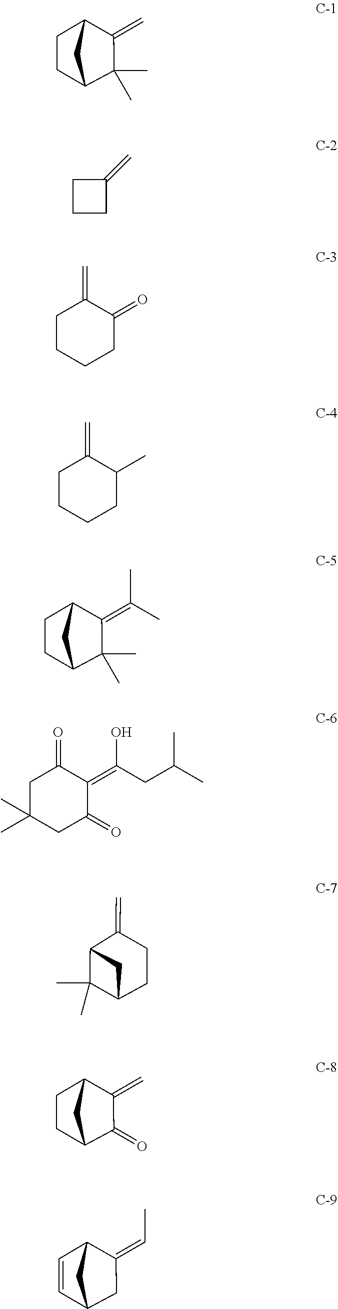

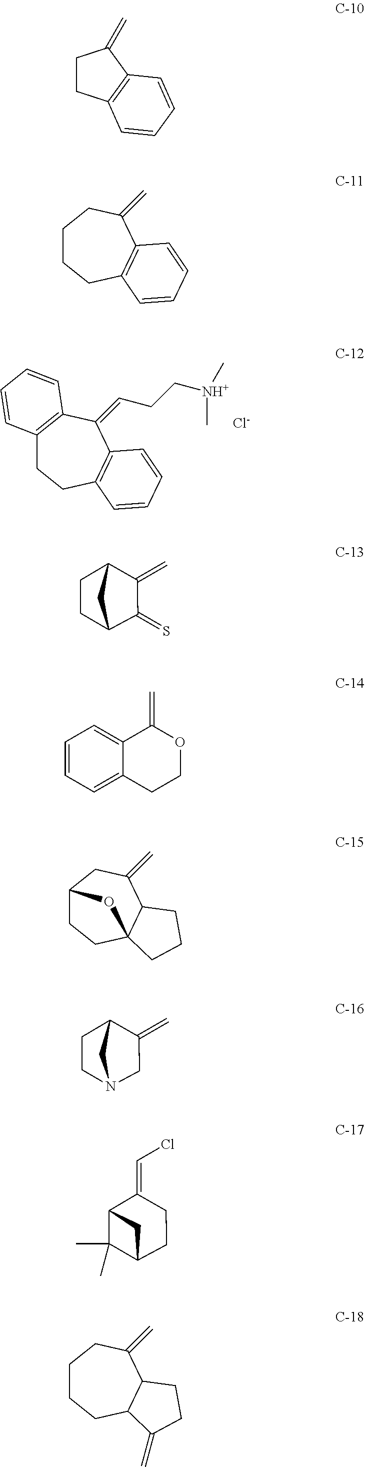

<Polymerizable Compound>

The curable composition according to the embodiment of the present invention can further contain a polymerizable compound having a polymerizable group. The polymerizable compound is preferably a radically polymerizable compound. Moreover, even in a case where the compound C is recognized as having polymerizability, the compound satisfying any one of Formula (C1), . . . , or (C3) is not included in the polymerizable compound in the present invention.

The polymerizable compound may be a monofunctional polymerizable compound having one polymerizable group, or a polyfunctional polymerizable compound having two or more polymerizable groups. The curable composition according to the embodiment of the present invention preferably contains a polyfunctional polymerizable compound, and more preferably contains both a polyfunctional polymerizable compound and a monofunctional polymerizable compound. The polyfunctional polymerizable compound preferably includes at least one kind of a bifunctional polymerizable compound or a trifunctional polymerizable compound, and more preferably includes at least one kind of bifunctional polymerizable compounds.

The polymerizable group of the polymerizable compound is preferably a radically polymerizable group, and more preferably includes a group having an ethylenically unsaturated bond. Examples of such a polymerizable group include groups having an ethylenically unsaturated bond, such as a vinyl group, an allyl group, a vinylphenyl group, a (meth)acryloyl group, a (meth)acryloyloxy group, and a (meth)acryloylamino group. The polymerizable group is preferably a (meth)acryloyl group, a (meth)acryloyloxy group, and a (meth)acryloylamino group, more preferably an acryloyl group, an acryloyloxy group, and an acryloylamino group, and particularly preferably a (meth)acryloyloxy group.

A molecular weight of the polymerizable compound in the present invention is preferably less than 2,000, more preferably 1,500 or less, and still more preferably 1,000 or less, and may be 800 or less. The lower limit value thereof is preferably 100 or greater.

The polymerizable compound in the present invention may or may not contain a silicon atom. As such an embodiment, a case where the polymerizable compound is a polymerizable compound having a silicone skeleton is exemplified. Moreover, as another embodiment, a case where the polymerizable compound is a polymerizable compound containing no silicon atom is exemplified. Examples of the polymerizable compound having a silicone skeleton include SILICONE ACRYLATE X-22-1602 produced by Shin-Etsu Chemical Co., Ltd.

A content of the polymerizable compound of the present invention is preferably 40% by mass or greater, more preferably 60% by mass or greater, still more preferably 70% by mass or greater, particularly preferably 80% by mass or greater, and even more preferably 90% by mass or greater, with respect to the entire curable composition. Moreover, the content of the polymerizable compound of the present invention is preferably 99.9% by mass or less, more preferably 99% by mass or less, and still more preferably 98% by mass or less, with respect to the entire curable composition.

The curable composition according to the embodiment of the present invention may contain only one kind or two or more kinds of the polymerizable compounds. In a case where two or more kinds thereof are contained, the total amount thereof is preferably within the above range.

<<Polyfunctional Polymerizable Compound>>

In a case where the polymerizable compound is a polyfunctional polymerizable compound, the number of polymerizable groups of the polyfunctional polymerizable compound used in the present invention is 2 or more, preferably 2 to 7, more preferably 2 to 4, still more preferably 2 or 3, and even more preferably 2.

In the present invention, the polyfunctional polymerizable compound preferably includes a compound represented by Formula (2). By using such a polyfunctional polymerizable compound, adhesiveness, releasability, and temporal stability in the imprinting are well-balanced, and thus the curable composition tends to be comprehensively superior.

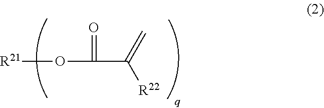

In the formula, R²¹ is a q-valent organic group, R²² is a hydrogen atom or a methyl group, and q is an integer of 2 or more. q is preferably an integer of 2 to 7, more preferably an integer of 2 to 4, still more preferably 2 or 3, and even more preferably 2.

R²¹ is preferably a divalent to heptavalent organic group, more preferably a divalent to tetravalent organic group, still more preferably a divalent or trivalent organic group, and even more preferably a divalent organic group. R²¹ is preferably a hydrocarbon group having at least one of a linear structure, a branched structure, or a cyclic structure. The number of carbon atoms in the hydrocarbon group is preferably 2 to 20 and more preferably 2 to 10.

In a case where R²¹ is a divalent organic group, R²¹ is preferably an organic group represented by Formula (1-2).

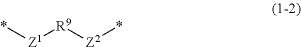

In the formula, it is preferable that Z¹ and Z² are each independently a single bond, —O—, -Alk-, or -Alk-O—. Alk represents an alkylene group (the number of the carbon atoms is preferably 1 to 12, more preferably 1 to 6, and still more preferably 1 to 3), and may have a substituent as long as the effects of the present invention are not impaired. In the present specification, the asterisk in the chemical formula indicates a bonding site.

R⁹ is a single bond or a divalent linking group. The linking group is preferably a linking group selected from Formulae (9-1) to (9-10), or a combination thereof. Among them, a linking group selected from Formulae (9-1) to (9-3), (9-7), and (9-8) is preferable.

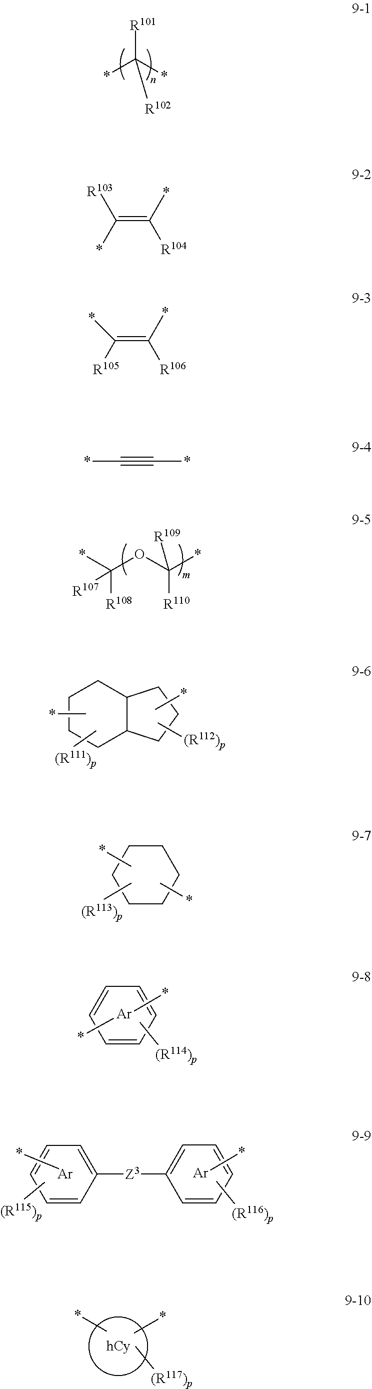

R¹⁰¹ to R¹¹⁷ are optional substituents. Among them, an alkyl group (the number of the carbon atoms is preferably 1 to 12, more preferably 1 to 6, and still more preferably 1 to 3), an arylalkyl group (the number of the carbon atoms is preferably 7 to 21, more preferably 7 to 15, and still more preferably 7 to 11), an aryl group (the number of the carbon atoms is preferably 6 to 22, more preferably 6 to 18, and still more preferably 6 to 10), a thienyl group, a furyl group, a (meth)acryloyl group, a (meth)acryloyloxy group, and a (meth)acryloyloxyalkyl group (the number of the carbon atoms in the alkyl group is preferably 1 to 24, more preferably 1 to 12, and still more preferably 1 to 6) are preferable. R¹⁰¹ and R¹⁰², R¹⁰³ and R¹⁰⁴, R¹⁰⁵ and R¹⁰⁶, R¹⁰⁷ and R¹⁰⁸, R¹⁰⁹ and R¹¹⁰, a plurality of R¹¹¹'s, a plurality of R¹¹²'s, a plurality of R¹¹³'s, a plurality of R¹¹⁴'s, a plurality of R¹¹⁵'s, a plurality of R¹¹⁶'s, and a plurality of R¹¹⁷'s may be respectively bonded to each other to form a ring.

Ar is an arylene group (the number of the carbon atoms is preferably 6 to 22, more preferably 6 to 18, and still more preferably 6 to 10), and specific examples thereof include a phenylene group, a naphthalenediyl group, an anthracenediyl group, a phenanthrenediyl group, and a fluorenediyl group.

hCy is a heterocyclic group (the number of the carbon atoms is preferably 1 to 12, more preferably 1 to 6, and still more preferably 2 to 5), and is more preferably a 5-membered ring or a 6-membered ring. Specific examples of a heterocyclic ring constituting hCy include a thiophene ring, a furan ring, a dibenzofuran ring, a carbazole ring, an indole ring, a tetrahydropyran ring, a tetrahydrofuran ring, a pyrrole ring, a pyridine ring, a pyrazole ring, an imidazole ring, a benzimidazole ring, a triazole ring, a thiazole ring, an oxazole ring, a pyrrolidone ring, and a morpholine ring, and among them, a thiophene ring, a furan ring, and a dibenzofuran ring are preferable.

Z³ is a single bond or a linking group. Examples of the linking group include alkylene groups (the number of the carbon atoms is preferably 1 to 12, more preferably 1 to 6, and still more preferably 1 to 3) in which an oxygen atom, a sulfur atom, and a fluorine atom may be substituted.

n and m are each a natural number of 100 or less, preferably 1 to 12, more preferably 1 to 6, and still more preferably 1 to 3.

p is 0 or more and is an integer equal to or less than the maximum number of groups which can be substituted for each ring. In the respective cases, the upper limit values are independently preferably equal to or less than half of the maximum number of the substitutable group, more preferably 4 or less, and still more preferably 2 or less.

The polyfunctional polymerizable compound is preferably represented by Formula (2-1).

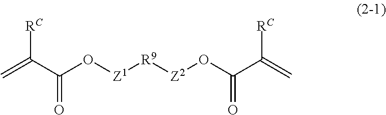

In Formula (2-1), R^{C} is a hydrogen atom or a methyl group. Moreover, R⁹, Z¹, and Z² have the same definitions as R⁹, Z¹, and Z² in Formula (1-2), respectively, and preferred ranges thereof are also the same.

A type of an atom constituting the polyfunctional polymerizable compound used in the present invention is not particularly specified, but the polyfunctional polymerizable compound is preferably constituted of only atoms selected from a carbon atom, an oxygen atom, a hydrogen atom, and a halogen atom, and more preferably constituted of only atoms selected from a carbon atom, an oxygen atom, and a hydrogen atom.

Examples of the polyfunctional polymerizable compound preferably used in the present invention include the following compounds. Moreover, the examples include the polymerizable compound described in JP2014-170949A, the contents of which are incorporated in the present specification.

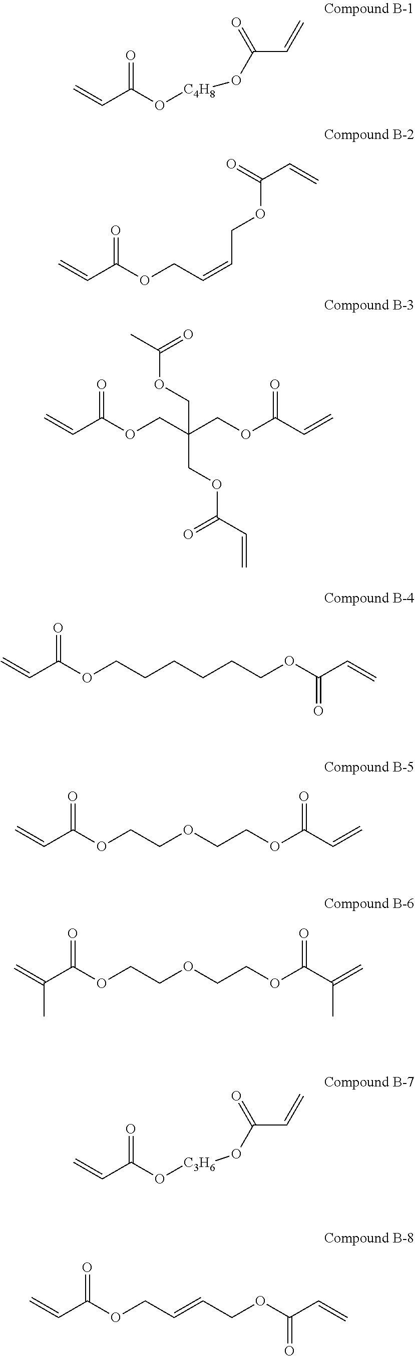

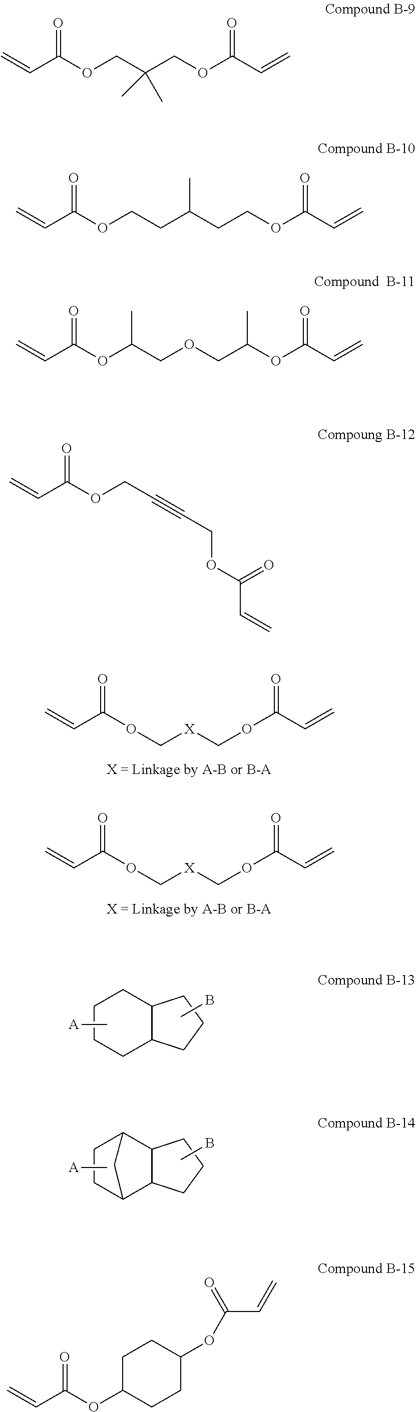

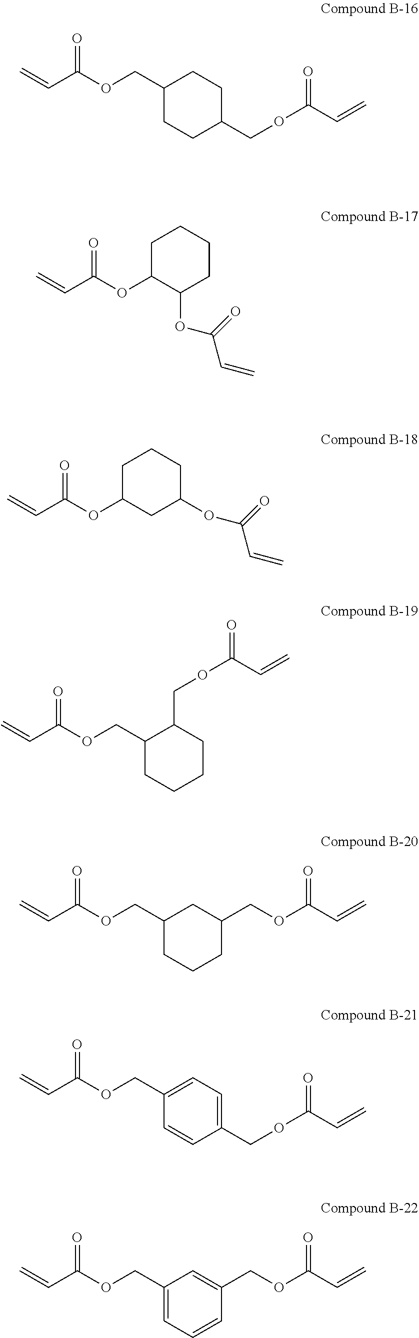

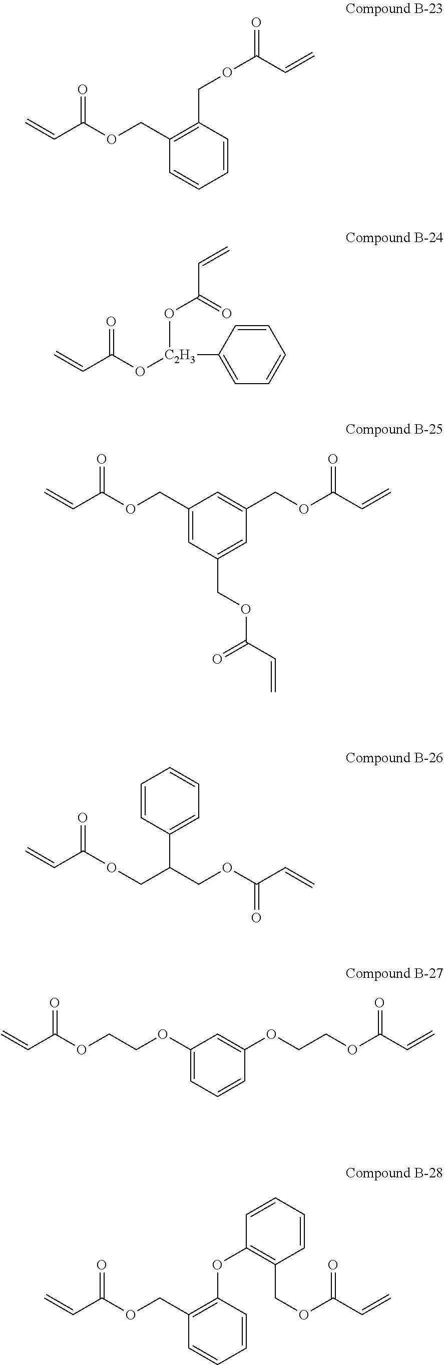

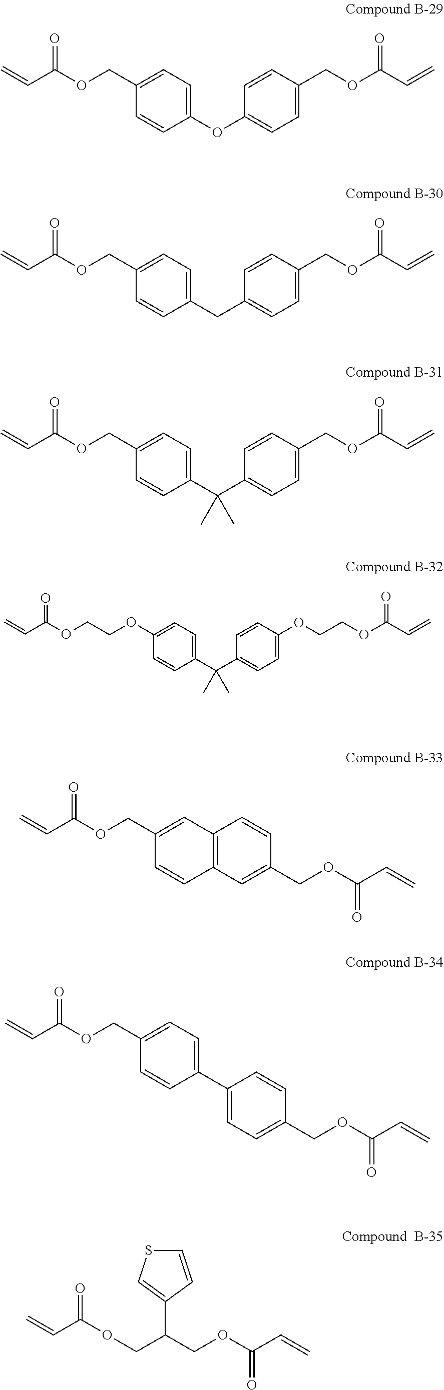

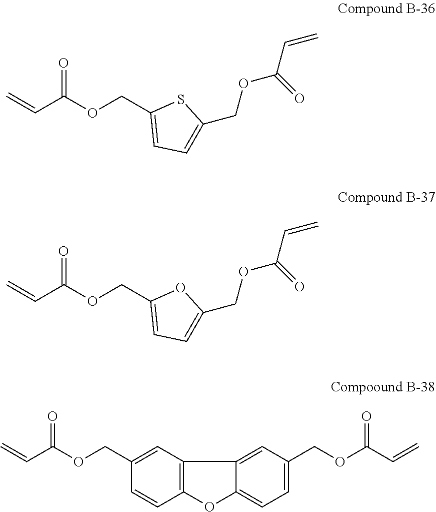

The content of the polyfunctional polymerizable compound used in the present invention is preferably 30% to 99% by mass, more preferably 50% to 95% by mass, and still more preferably 75% to 90% by mass, and may be 80% to 90% by mass, with respect to the total polymerizable compound in the composition. The curable composition may contain only one kind or two or more kinds of the polyfunctional polymerizable compounds. In a case where two or more kinds thereof are contained, the total amount thereof is preferably within the above range.

<<Monofunctional Polymerizable Compound>>

In the curable composition according to the embodiment of the present invention, in a case where the polymerizable compound is a monofunctional polymerizable compound, the type thereof is not particularly specified as long as the type does not depart from the spirit of the present invention. It is preferable that the monofunctional polymerizable compound used in the present invention has a cyclic structure, or a linear or branched hydrocarbon chain having 4 or more carbon atoms. In the present invention, only one kind or two or more kinds of the monofunctional polymerizable compounds may be contained.

The monofunctional polymerizable compound used in the present invention is preferably a liquid at 25° C.

In the present invention, the compound which is a liquid at 25° C. means a compound having fluidity at 25° C., for example, a compound having a viscosity at 25° C. of 1 to 100,000 mPa·s. For example, the viscosity of the monofunctional polymerizable compound at 25° C. is more preferably 10 to 20,000 mPa·s and still more preferably 100 to 15,000 mPa·s.

By using a compound which is a liquid at 25° C., a configuration in which the curable composition does not substantially contain a solvent can be adopted. Here, the expression “not substantially contain a solvent” means, for example, that the content of the solvent in the curable composition according to the embodiment of the present invention is 5% by mass or less. The content of the solvent in the curable composition is preferably 3% by mass or less and more preferably 1% by mass or less.

The viscosity of the monofunctional polymerizable compound used in the present invention at 25° C. is preferably 100 mPa·s or lower, more preferably 10 mPa·s or lower, still more preferably 8 mPa·s or lower, and even more preferably 6 mPa·s or lower. By setting the viscosity of the monofunctional polymerizable compound at 25° C. to be equal to or lower than the upper limit value, the viscosity of the curable composition can be reduced, and thus filling properties tend to be improved. The lower limit value thereof is not particularly specified, but can be, for example, 1 mPa·s or higher.

The monofunctional polymerizable compound used in the present invention is preferably a monofunctional (meth)acrylic monomer and more preferably monofunctional acrylate.

A type of an atom constituting the monofunctional polymerizable compound used in the present invention is not particularly specified, but the monofunctional polymerizable compound is preferably constituted of only atoms selected from a carbon atom, an oxygen atom, a hydrogen atom, and a halogen atom, and more preferably constituted of only atoms selected from a carbon atom, an oxygen atom, and a hydrogen atom.

The monofunctional polymerizable compound used in the present invention preferably has a plastic structure. For example, it is preferable that at least one kind of the monofunctional polymerizable compounds used in the present invention contains one group selected from the group consisting of the following (1) to (3).

(1) A group (hereinafter, referred to as a “group (1)” in some cases) which has at least one of an alkyl chain or an alkenyl chain and at least one of an alicyclic structure or an aromatic ring structure, and has the total number of carbon atoms of 7 or more

(2) A group (hereinafter, referred to as a “group (2)” in some cases) having an alkyl chain having 4 or more carbon atoms

(3) A group (hereinafter, referred to as a “group (3)” in some cases) having an alkenyl chain having 4 or more carbon atoms

With such a configuration, a modulus of elasticity of a cured film can be efficiently reduced while reducing the addition amount of the monofunctional polymerizable compound contained in the curable composition. Moreover, interfacial energy with the mold is reduced, and thus an effect of reducing a releasing force (effect of improving releasability) can be enhanced.

In the groups (1) to (3), the alkyl chain and the alkenyl chain may be linear, branched, or cyclic, and are each independently preferably linear or branched. Moreover, it is preferable that the groups (1) to (3) have the alkyl chain and/or an alkenyl chain at a terminal of the monofunctional polymerizable compound, that is, an alkyl group and/or an alkenyl group. With such a structure, the releasability can be further improved.

The alkyl chain and the alkenyl chain may each independently contain an ether group (—O—), but it is preferable that an ether group is not contained from the viewpoint of improvement in the releasability.

Group (1)

The total number of carbon atoms in the group (1) is preferably 35 or less and more preferably 10 or less.

As the cyclic structure, a single ring or a fused ring of 3- to 8-membered rings is preferable. The number of rings constituting the fused ring is preferably 2 or 3. The cyclic structure is more preferably a 5-membered ring or a 6-membered ring and still more preferably a 6-membered ring. Moreover, a single ring is more preferable. As the cyclic structure in the group (1), a cyclohexane ring, a benzene ring, and a naphthalene ring are more preferable, and a benzene ring is particularly preferable. Moreover, the cyclic structure is preferably an aromatic ring structure.

The number of cyclic structures in the group (1) may be 1 or may be 2 or more, but is preferably 1 or 2 and more preferably 1. Furthermore, in a case of the fused ring, the fused ring is considered as one cyclic structure.

Group (2)

The group (2) is a group having an alkyl chain having 4 or more carbon atoms, and preferably a group (that is, an alkyl group) consisting of an alkyl chain having 4 or more carbon atoms. The number of carbon atoms in the alkyl chain is preferably 7 or more and more preferably 9 or more. The upper limit value of the number of carbon atoms in the alkyl chain is not particularly limited, but can be, for example, 25 or less. Moreover, a compound in which some carbon atoms of the alkyl chain are substituted with silicon atoms can also be exemplified as the monofunctional polymerizable compound.

Group (3)

The group (3) is a group having an alkenyl chain having 4 or more carbon atoms, and preferably a group (that is, an alkylene group) consisting of an alkenyl chain having 4 or more carbon atoms. The number of carbon atoms in the alkenyl chain is preferably 7 or more and more preferably 9 or more. The upper limit value of the number of carbon atoms in the alkenyl chain is not particularly limited, but can be, for example, 25 or less.

The monofunctional polymerizable compound used in the present invention is preferably a compound in which any one or more of the group (1), . . . , or (3) are bonded to a polymerizable group directly or via a linking group, and more preferably a compound in which any one of the group (1), . . . , or (3) is directly bonded to a polymerizable group. Examples of the linking group include —O—, —C(═O)—, —CH₂—, —NH—, or a combination thereof.

Specific examples of the monofunctional polymerizable compound are as follows. However, in the present invention, the monofunctional polymerizable compound is not limited to the following compounds.

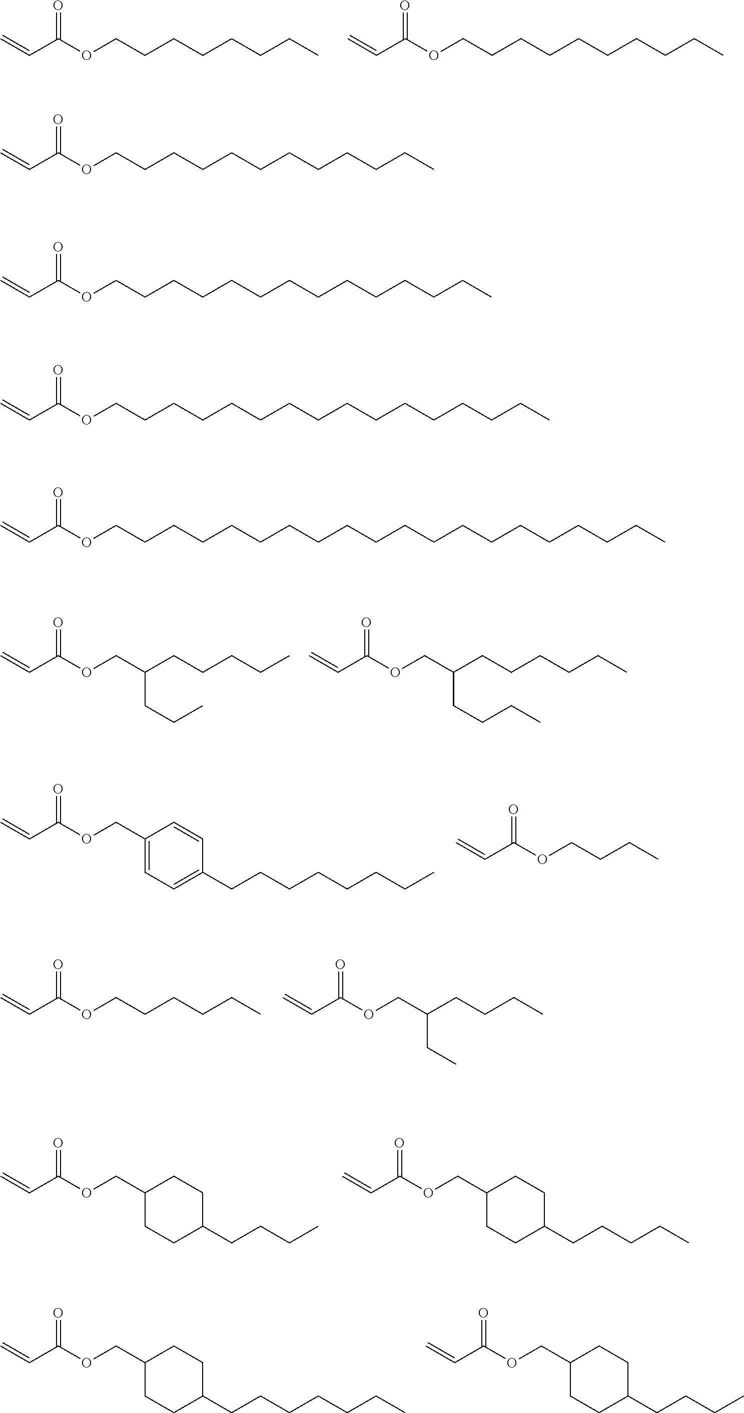

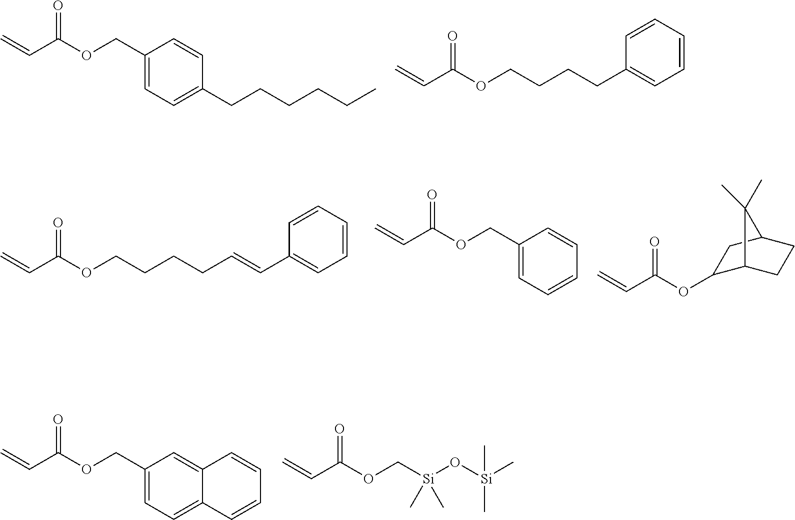

The lower limit value of an amount of the monofunctional polymerizable compound with respect to the total polymerizable compounds in the curable composition is preferably 1% by mass or greater, more preferably 3% by mass or greater, still more preferably 5% by mass or greater, and even more preferably 7% by mass or greater. Moreover, the upper limit value thereof is more preferably 29% by mass or less, still more preferably 27% by mass or less, even more preferably 25% by mass or less, further still more preferably 20% by mass or less, and further still more preferably 15% by mass or less. By setting the amount of the monofunctional polymerizable compound with respect to the total polymerizable compounds to be equal to or greater than the lower limit value, the releasability can be improved, and thus pattern defects or damage to the mold can be suppressed in a case of releasing the mold. Furthermore, by setting the amount to be equal to or less than the upper limit value, a Tg of a cured film of the curable composition can be increased, and thus resistance to etching processing, in particular, waviness of a pattern during etching can be suppressed.

In the present invention, monofunctional polymerizable compounds other than the aforementioned monofunctional polymerizable compound may be used as long as the compounds do not depart from the spirit of the present invention, and examples thereof include the monofunctional polymerizable compounds among the polymerizable compounds described in JP2014-170949A, the contents of which are incorporated in the present specification.

In addition, in the curable composition according to the embodiment of the present invention, a configuration in which a cationically polymerizable compound (compound which has a cationically polymerizable group such as an epoxy group, an isobutene group, and a vinyl ether group, and does not have a radically polymerizable group) is not substantially contained can also be adopted. The expression “cationically polymerizable compound is not substantially contained” means that the content of the cationically polymerizable compound is less than 5% by mass with respect to the amount of the total solid content in the composition. Moreover, the content of the cationically polymerizable compound is preferably less than 1% by mass and more preferably less than 0.1% by mass with respect to the amount of the total solid content in the composition.

<Radical Polymerization Initiator>

The curable composition according to the embodiment of the present invention contains a radical polymerization initiator. The radical polymerization initiator may be a thermal radical polymerization initiator or a photoradical polymerization initiator, and is preferably a photoradical polymerization initiator. As the photoradical polymerization initiator used in the present invention, any compound can be used as long as the compound generates an active species which polymerizes the aforementioned polymerizable compounds by light irradiation.

In the photoradical polymerization initiator, a maximum value of a molar absorption coefficient in a wavelength range of 250 to 400 nm in an acetonitrile solution is 5,000 L/(mol·cm) or greater, preferably 10,000 L/(mol·cm) or greater, and more preferably 15,000 L/(mol·cm) or greater. The upper limit of the maximum value of the molar absorption coefficient is practically, for example, 100,000 L/(mol·cm) or less and further, 50,000 L/(mol·cm) or less.

A molecular weight of the photoradical polymerization initiator is not particularly limited, but is preferably 100 or greater, more preferably 120 or greater, and still more preferably 150 or greater. The upper limit thereof is preferably 2,000 or less, more preferably 1,500 or less, and still more preferably 1,000 or less.

As the photoradical polymerization initiator, an alkylphenone-based compound, an acetophenone-based compound, an acylphosphine oxide-based compound, and an oxime ester-based compound are preferable from the viewpoints of curing sensitivity and absorption characteristics. Here, the oxime ester means a compound having a linking structure represented by Formula (1) in a molecule, and preferably has a linking structure represented by Formula (2). * in the formula indicates a bonding site bonded to an organic group. In the present invention, as the photoradical polymerization initiator, for example, commercially available initiators can be used. As examples thereof, the initiators described in, for example, paragraph 0091 of JP2008-105414A can be preferably adopted.

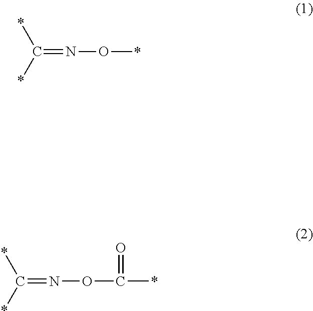 [SMILES: *ON=C(*)* ; *C(=O)ON=C(*)*]

Examples of a commercially available product thereof include IRGACURE (registered trademark) 1173, IRGACURE 184, IRGACURE 2959, IRGACURE 127, IRGACURE 907, IRGACURE 369, IRGACURE 379, LUCIRIN (registered trademark) TPO, IRGACURE 819, IRGACURE OXE-01, IRGACURE OXE-02, IRGACURE 651, and IRGACURE 754 (all produced by BASF SE), Omnirad 369 and Omnirad 651 (all produced by IGM Resins B.V.), and V-601 (produced by FUJIFILM Wako Pure Chemical Corporation).

In the present invention, an oxime compound having a fluorine atom can also be used as the photoradical polymerization initiator. Specific examples of the oxime compound having a fluorine atom include the compound described in JP2010-262028A, the compounds 24 and 36 to 40 described in JP2014-500852A, and the compound (C-3) described in JP2013-164471A. The contents thereof are incorporated in the present specification.

One kind of the photoradical polymerization initiators may be used singly, but it is also preferable to use two or more kinds thereof in combination. Specific examples thereof include combinations of DAROCUR 1173 and IRGACURE 907, DAROCUR 1173 and LUCIRIN TPO, DAROCUR 1173 and IRGACURE 819, DAROCUR 1173 and IRGACURE OXE 01, IRGACURE 907 and LUCIRIN TPO, and IRGACURE 907 and IRGACURE 819. By using such a combination, an exposure margin can be expanded.

In the curable composition according to the embodiment of the present invention, the content of the photoradical polymerization initiator is preferably 0.01% to 10% by mass with respect to the amount of the total solid content in the composition. The upper limit of the numerical range is more preferably 5% by mass or less and still more preferably 3% by mass or less. Moreover, the lower limit of the numerical range is more preferably 0.1% by mass or greater and still more preferably 0.5% by mass or greater. The curable composition may contain only one kind or two or more kinds of the photoradical polymerization initiators. In a case where two or more kinds of the photoradical polymerization initiators are contained, the total amount thereof is preferably within the above range.

Furthermore, in the curable composition according to the embodiment of the present invention, a configuration in which a cationic polymerization initiator is not substantially contained can also be adopted. The expression “cationic polymerization initiator is not substantially contained” means that the content of the cationic polymerization initiator is less than 1% by mass with respect to the amount of the total solid content in the composition. Moreover, the content of the cationic polymerization initiator is preferably less than 0.1% by mass, more preferably less than 0.01% by mass, and still more preferably less than 0.005% by mass, with respect to the amount of the total solid content in the composition.

<Release Agent>

The curable composition according to the embodiment of the present invention may contain a release agent.

A type of the release agent used in the present invention is not particularly specified as long as the type does not depart from the spirit of the present invention. The release agent is preferably an additive having a function of segregating at an interface with the mold to promote separation from the mold. Specific examples thereof include a surfactant, and a non-polymerizable compound (hereinafter, referred to as a “non-polymerizable compound having releasability” in some cases) which has a polyalkylene glycol structure having at least one hydroxyl group at the terminal or having an etherified hydroxyl group, and does not substantially contain a fluorine atom and a silicon atom.

The release agent in the curable composition may be of only one kind or two or more kinds. Moreover, in a case where the release agent is contained, a total content thereof with respect to the total solid content is preferably 0.1% to 20% by mass, more preferably 0.5% to 10% by mass, and still more preferably 1% to 5% by mass. In a case where two or more kinds of the release agents are used, the total amount thereof is preferably within the above range.

<<Surfactant>>

As a surfactant for the release agent, a nonionic surfactant is preferable.

The nonionic surfactant is a compound having at least one hydrophobic moiety and at least one nonionic hydrophilic moiety. The hydrophobic moiety and the nonionic hydrophilic moiety may each be at a terminal of a molecule, or inside. The hydrophobic moiety is constituted of a hydrophobic group selected from a hydrocarbon group, a fluorine-containing group, and a Si-containing group, and the number of carbon atoms in the hydrophobic moiety is preferably 1 to 25, more preferably 2 to 15, still more preferably 4 to 10, and even more preferably 5 to 8. The nonionic hydrophilic moiety preferably has at least one group selected from the group consisting of an alcoholic hydroxyl group, a phenolic hydroxyl group, an ether group (preferably, a polyoxyalkylene group and a cyclic ether group), an amide group, an imide group, a ureide group, a urethane group, a cyano group, a sulfonamide group, a lactone group, a lactam group, and a cyclocarbonate group. The nonionic surfactant may be a hydrocarbon-based, fluorine-based, Si-based, or fluorine and Si-based nonionic surfactant, but is more preferably a fluorine-based or Si-based nonionic surfactant and still more preferably a fluorine-based nonionic surfactant. Here, the “fluorine and Si-based surfactant” refers to a surfactant satisfying requirements of both a fluorine-based surfactant and a Si-based surfactant.

Examples of a commercially available product of the fluorine-based nonionic surfactant include FLUORAD FC-4430 and FC-4431 produced by Sumitomo 3M Limited, SURFLON S-241, S-242, S-243, and S-650 produced by AGC SEIMI CHEMICAL CO., LTD., EFTOP EF-PN31M-03, EF-PN31M-04, EF-PN31M-05, EF-PN31M-06, and MF-100 produced by Mitsubishi Materials Electronic Chemicals Co., Ltd., Polyfox PF-636, PF-6320, PF-656, and PF-6520 produced by OMNOVA Solutions Inc., FUTAGENT 250, 251, 222F, and 212M DFX-18 produced by NEOS COMPANY LIMITED, UNIDYNE DS-401, DS-403, DS-406, DS-451, and DSN-403N produced by DAIKIN INDUSTRIES, LTD., MEGAFACE F-430, F-444, F-477, F-553, F-556, F-557, F-559, F-562, F-565, F-567, F-569, and R-40 produced by DIC Corporation, and Capstone FS-3100 and Zonyl FSO-100 produced by DuPont.

In a case where the curable composition according to the embodiment of the present invention contains a surfactant, a content of the surfactant is preferably 0.1% to 10% by mass, more preferably 0.2% to 5% by mass, and still more preferably 0.5% to 5% by mass in the entire composition excluding a solvent. The curable composition may contain only one kind or two or more kinds of the surfactants. In a case where two or more kinds thereof are contained, the total amount thereof is preferably within the above range.

<<Non-Polymerizable Compound Having Releasability>>

The curable composition according to the embodiment of the present invention may contain, as the release agent, a non-polymerizable compound which has a polyalkylene glycol structure having at least one hydroxyl group at the terminal or having an etherified hydroxyl group, and does not substantially contain a fluorine atom and a silicon atom. Here, the non-polymerizable compound refers to a compound having no polymerizable group. Moreover, regarding the non-polymerizable compound, the expression “does not substantially contain a fluorine atom and a silicon atom” indicates, for example, that a total content ratio of the fluorine atom and the silicon atom is 1% by mass or less, and it is preferable that a fluorine atom and a silicon atom are not contained at all. By not having a fluorine atom and a silicon atom, compatibility with the polymerizable compound is improved, and particularly in the curable composition which does not substantially contain a solvent, coating uniformity, pattern formability during imprinting, and line edge roughness after dry etching are improved.

The polyalkylene glycol structure of the non-polymerizable compound having releasability is preferably a polyalkylene glycol structure including an alkylene group having 1 to 6 carbon atoms, more preferably a polyethylene glycol structure, a polypropylene glycol structure, a polybutylene glycol structure, or a mixed structure thereof, still more preferably a polyethylene glycol structure, a polypropylene glycol structure, or a mixed structure thereof, and even more preferably a polypropylene glycol structure.

Furthermore, the non-polymerizable compound may be substantially constituted of only a polyalkylene glycol structure, except for a substituent at a terminal. Here, the expression “substantially” means that constituent elements other than the polyalkylene glycol structure account for 5% by mass or less and preferably 1% by mass or less of the entire compound. It is particularly preferable to include a compound substantially consisting of a polypropylene glycol structure, as the non-polymerizable compound having releasability.

The number of alkylene glycol constitutional units included in the polyalkylene glycol structure is preferably 3 to 100, more preferably 4 to 50, still more preferably 5 to 30, and even more preferably 6 to 20.

The non-polymerizable compound having releasability preferably has at least one hydroxyl group at the terminal or has an etherified hydroxyl group. In a case where the non-polymerizable compound has at least one hydroxyl group at the terminal or has an etherified hydroxyl group, the remaining terminals may be hydroxyl groups, or a hydrogen atom of the terminal hydroxyl group may be substituted. As a group in which a hydrogen atom of the terminal hydroxyl group may be substituted, an alkyl group (that is, polyalkylene glycol alkyl ether) and an acyl group (that is, polyalkylene glycol ester) are preferable. A compound having a plurality of (preferably, two or three) polyalkylene glycol chains via a linking group can also be preferably used.

Preferred specific examples of the non-polymerizable compound having releasability include polyethylene glycol, polypropylene glycol (for example, produced by FUJIFILM Wako Pure Chemical Corporation), mono or dimethyl ether thereof, mono or dibutyl ether, mono or dioctyl ether, mono or dicetyl ether, monostearate, monooleate, polyoxyethylene glyceryl ether, polyoxypropylene glyceryl ether, polyoxyethylene lauryl ether, and trimethyl ether thereof.

A weight-average molecular weight of the non-polymerizable compound having releasability is preferably 150 to 6,000, more preferably 200 to 3,000, still more preferably 250 to 2,000, and even more preferably 300 to 1,200.

In addition, examples of a commercially available product of the non-polymerizable compound having releasability, which can be used in the present invention, include OLFINE E1010 (produced by Nissin Chemical Co., Ltd.) and Brij35 (produced by Kishida Chemical Co., Ltd.).

In a case where the curable composition according to the embodiment of the present invention contains the non-polymerizable compound having releasability, a content of the non-polymerizable compound having releasability is preferably 0.1% by mass or greater, more preferably 0.5% by mass or greater, still more preferably 1.0% by mass or greater, and even more preferably 2% by mass or greater, in the total solid content. Moreover, the content is preferably 20% by mass or less, more preferably 10% by mass or less, and still more preferably 5% by mass or less.

The curable composition may contain only one kind or two or more kinds of the non-polymerizable compounds having releasability. In a case where two or more kinds thereof are contained, the total amount thereof is preferably within the above range.

<Other Components>

The curable composition according to the embodiment of the present invention may contain a sensitizer, an antioxidant, an ultraviolet absorber, a solvent, a polymer, or the like, in addition to the aforementioned components. Each of these compounds in the curable composition may be of only one kind or two or more kinds. For the details thereof, reference can be made to the description in paragraphs 0061 to 0064 of JP2014-170949A, the contents of which are incorporated in the present specification.

<<Solvent>>

The curable composition for imprinting according to the embodiment of the present invention may contain a solvent. Examples of the solvent include propylene glycol monomethyl ether acetate, cyclohexanone, 2-heptanone, γ-butyrolactone, propylene glycol monomethyl ether, and ethyl lactate. In a case where the solvent is contained, a content thereof is preferably 1% to 20% by mass with respect to the composition. Only one kind or two or more kinds of the solvents may be contained. In a case where two or more kinds thereof are contained, the total amount thereof is preferably within the above range.

Furthermore, in the present invention, a configuration in which a solvent is not substantially contained can also be adopted. The expression “solvent is not substantially contained” means that the content of the solvent is 5% by mass or less, and the content is preferably 3% by mass or less and more preferably 1% by mass or less.

<<Polymer>>

The curable composition according to the embodiment of the present invention may contain a polymer. The polymer is, for example, a component having a weight-average molecular weight of 2,000 or greater, and preferably a component having a weight-average molecular weight of greater than 2,000.

Furthermore, in the present invention, a configuration in which a polymer is not substantially contained can also be adopted. The expression “polymer is not substantially contained” means that the content of the polymer is 5% by mass or less, and the content is preferably 3% by mass or less and more preferably 1% by mass or less.

[Method for Producing Curable Composition]

The curable composition according to the embodiment of the present invention is prepared by formulating raw materials (the respective materials described above) in a predetermined ratio. It is preferable that the raw materials are mixed and then the mixture is subjected to a filtration treatment with a filter. The filtration with a filter is preferably performed after the raw materials of the curable composition are mixed.

Effects of filtration are exhibited even with one stage of a filter, but filtration with two or more stages of filters is more preferable. The filtration with two or more stages of filters refers to filtration in a state where two or more filters are arranged in series. In the present invention, filtration with one to four stages of filters is preferable, and filtration with two to four stages of filters is more preferable.

A component (material component) constituting the material for the filter preferably includes a resin. The resin is not particularly limited, and resins well-known as the material for the filter can be used. As one preferred embodiment of the component (material component) constituting the material for the filter, a polymer (grafted polymer) in which at least one kind of neutral groups is grafted can be mentioned. The neutral group is preferably at least one kind selected from a hydroxyl group or a carboxyl group, and more preferably a hydroxyl group. The grafted polymer is preferably a grafted polyolefin and more preferably a grafted polyethylene. For the description of the grafted polymer, reference can be made to the description in WO2016/081729A, the contents of which are incorporated in the present specification.

A pore diameter of the filter used in the present invention is preferably 100 nm or smaller, more preferably 20 nm or smaller, still more preferably 12 nm or smaller, and even more preferably 8 nm or smaller, and may be 5 nm or smaller. By setting the pore diameter of the filter to 100 nm or smaller, impurities can be further effectively reduced. Moreover, the lower limit value of the pore diameter of the filter is not particularly specified, but is, for example, preferably 1 nm or larger. By setting the pore diameter of the filter to 1 nm or larger, an unnecessarily large pressure is not applied during filtration, productivity is improved, and breakage of a filter can be effectively suppressed. In a case where the filtration is performed stepwise, a filter having a pore diameter of 100 to 7 nm (preferably, a filter having a pore diameter of 20 to 7 nm) can be used in first-stage filtration, and a filter having a pore diameter of smaller than 7 nm (preferably, a filter having a pore diameter of smaller than 7 nm and 1 nm or larger) can be used in second-stage filtration. Moreover, a difference in the pore diameter from the immediately preceding stage, such as between the first stage and the second stage and between the second stage and the third stage, is preferably 1 to 8 nm.

<Storage Container>

As a storage container of the curable composition according to the embodiment of the present invention, a storage container well-known in the related art can be used. Moreover, as the storage container, for the purpose of suppressing impurities from being mixed into a raw material or a composition, a multilayer bottle having a container inner wall made of six layers of six kinds of resins or a bottle having a seven-layer structure of six kinds of resins is also preferably used. Examples of such a container include the container described in JP2015-123351A.

[Pattern Producing Method]

The curable composition according to the embodiment of the present invention is used as a cured product. More specifically, the curable composition according to the embodiment of the present invention is used for producing a patterned cured product (hereinafter, also simply referred to as a “pattern”) by an optical imprint method.

A pattern producing method according to the embodiment of the present invention includes applying the photocurable composition according to the embodiment of the present invention onto a substrate or a mold and irradiating the photocurable composition with light in a state where the photocurable composition is sandwiched between the mold and the substrate. The method for applying the photocurable composition onto the substrate or the mold is not particularly limited. Regarding the application method, reference can be made to the description in paragraph 0102 of JP2010-109092A (the corresponding US application is the specification of US2011/0199592A), the contents of which are incorporated in the present specification. In the present invention, as the application method, a spin coating method or an ink jet method is preferable.

In the present invention, the substrate is not particularly limited. Regarding the substrate, reference can be made to the description in paragraph 0103 of JP2010-109092A (the corresponding US application is the specification of US2011/0199592A), the contents of which are incorporated in the present specification. Specific examples thereof include a silicon substrate, a glass substrate, a sapphire substrate, a silicon carbide substrate, a gallium nitride substrate, a metal aluminum substrate, an amorphous aluminum oxide substrate, a polycrystalline aluminum oxide substrate, and a substrate made of GaAsP, GaP, AlGaAs, InGaN, GaN, AlGaN, ZnSe, AlGaInP, or ZnO. Furthermore, specific examples of a material for the glass substrate include aluminosilicate glass, aluminoborosilicate glass, and barium borosilicate glass. In the present invention, as the substrate, a silicon substrate is preferable.

In the present invention, the mold is not particularly limited. Regarding the mold, reference can be made to the description in paragraphs 0105 to 0109 of JP2010-109092A (the corresponding US application is the specification of US2011/0199592A), the contents of which are incorporated in the present specification. In the present invention, as the mold, a quartz mold is preferable. A pattern (line width) of the mold used in the present invention preferably has a size of 50 nm or less.

The curable composition is irradiated with light in a state of being sandwiched between the mold and the substrate. A step of performing pressure contact with the substrate or the mold can be preferably performed under a rare gas atmosphere, under a reduced-pressure atmosphere, or under a pressure-reduced rare gas atmosphere. Here, the reduced-pressure atmosphere means a state in a space filled with a pressure lower than the atmospheric pressure (101,325 Pa), and the pressure is preferably 1,000 Pa or lower, more preferably 100 Pa or lower, and still more preferably 1 Pa or lower. In a case where the rare gas is used, helium is preferable. An exposure dose is desirably in a range of 5 mJ/cm² to 1,000 mJ/cm².

Here, an underlayer film or a liquid film may be provided between the substrate and the curable composition layer, by using a composition for forming an underlayer film or a composition for forming a liquid film. That is, the curable composition (further, a cured product of the present invention) may be provided directly on the surface of the substrate or the mold, or may be provided on the substrate or the mold via one or more layers. The underlayer film and the liquid film will be described in detail later.

In addition to the aforementioned matters, for details of the pattern producing method, reference can be made to the description in paragraphs 0103 to 0115 of JP2010-109092A (the corresponding US application is the specification of US2011/0199592A), the contents of which are incorporated in the present specification.

In the pattern producing method according to the embodiment of the present invention, a fine pattern can be formed at a low cost and with high accuracy by the optical imprint method (more preferably, an optical nanoimprint method). Therefore, the pattern, which was used to be formed by using the photolithography technique in the related art, can be formed with higher accuracy and at a lower cost. As an example, the method is used for manufacturing a semiconductor element. That is, the present invention also discloses a method for manufacturing a semiconductor element, which includes the pattern producing method according to the embodiment of the present invention. More specifically, the pattern of the present invention is preferably used as an etching resist (etching mask). In particular, the pattern can also be applied as a permanent film, such as an overcoat layer or an insulating film, used in a liquid crystal display (LCD) or the like, or an etching resist such as a semiconductor integrated circuit, a recording material, or a flat panel display. In particular, the pattern obtained by the pattern producing method according to the embodiment of the present invention also has excellent etching resistance, and thus can also be preferably used as an etching resist for dry etching using fluorocarbon or the like.

<Pattern>

As described above, the pattern formed by the pattern producing method according to the embodiment of the present invention can be used as a permanent film used in an LCD or the like, or an etching resist for semiconductor processing. Moreover, a grid pattern is formed on a glass substrate of the LCD using the pattern of the present invention, and thus a polarizing plate having low reflection or absorption and a large screen size (for example, 55 inches, or greater than 60 inches) can be manufactured at a low cost. For example, the polarizing plate described in JP2015-132825A or W02011/132649A can be manufactured. Furthermore, 1 inch is 25.4 mm.

In addition, after the production, the curable composition is bottled in a container such as a gallon bottle or a coated bottle, transported, and stored, but in this case, for the purpose of preventing deterioration, the inside of the container may be replaced with inert nitrogen, argon, or the like. Moreover, during the transportation and the storage, the temperature may be a normal temperature, but in order to further prevent degeneration of the curable composition, the temperature may be controlled to be in a range of −20° C. to 0° C. It goes without saying that blocking light at a level at which the reaction does not proceed is preferable.

Specifically, the pattern of the present invention can be preferably used for producing a recording medium such as a magnetic disc, a light-receiving element such as a solid-state imaging element, a light emitting element such as an LED and organic EL, an optical device such as an LCD, an optical component such as a diffraction grating, a relief hologram, an optical waveguide, an optical filter, and a microlens array, a member for flat panel display such as a thin film transistor, an organic transistor, a color filter, an antireflection film, a polarizing plate, a polarizing element, an optical film, and a column material, a nanobiodevice, an immunoassay chip, a deoxyribonucleic acid (DNA) separation chip, a microreactor, a photonic liquid crystal, or a guide pattern for fine pattern formation (directed self-assembly, DSA) using self-assembly of block copolymers.

The pattern formed by the pattern producing method according to the embodiment of the present invention is also useful as an etching resist (mask for lithography). In a case where the pattern is used as an etching resist, first, a silicon substrate (silicon wafer or the like) in which a thin film of SiO₂ or the like is formed or the like is used as a substrate, and a fine pattern of, for example, a nano or micro order is formed on the substrate by the pattern producing method according to the embodiment of the present invention. In the present invention, the pattern producing method is particularly advantageous in that a fine pattern of a nano order can be formed and a pattern having a size of 100 nm or less, further 50 nm or less, and particularly 30 nm or less can also be formed. The lower limit value of the size of the pattern formed by the pattern producing method according to the embodiment of the present invention is not particularly specified, but can be, for example, 1 nm or greater. A shape of the pattern is not particularly specified, but, for example, an aspect including at least one shape of a line, a hole, or a pillar is exemplified.

Thereafter, by performing etching with an etching gas such as hydrogen fluoride or the like in a case of wet etching and CF₄ or the like in a case of dry etching, a desired pattern can be formed on the substrate. The pattern has favorable etching resistance particularly to dry etching. That is, the pattern obtained by the producing method according to the embodiment of the present invention is preferably used as an etching mask. Moreover, the present invention also discloses a method for manufacturing a semiconductor element, in which etching is performed using, as a mask, the pattern obtained by the producing method according to the embodiment of the present invention.

[Composition for Forming Underlayer film]

As described above, by providing the underlayer film between the substrate and the curable composition layer, effects such as improvement in the adhesiveness between the substrate and the curable composition layer can be achieved. In the present invention, the underlayer film can be obtained by applying the composition for forming an underlayer film onto the substrate and then curing the composition, in the same manner as the curable composition. Hereinafter, each component of the composition for forming an underlayer film will be described.

The composition for forming an underlayer film of the present invention contains a curable component. The curable component is a component constituting the underlayer film, and may be any one of a high-molecular-weight component (for example, a molecular weight is greater than 1,000) or a low-molecular-weight component (for example, a molecular weight is less than 1,000). Specific examples thereof include a resin and a crosslinking agent. Only one kind or two or more kinds of the respective components may be used.

A total content of the curable components in the composition for forming an underlayer film is not particularly limited, but is preferably 50% by mass or greater in the total solid content, more preferably 70% by mass or greater in the total solid content, and still more preferably 80% by mass or greater in the total solid content. The upper limit thereof is not particularly limited, but is preferably 99.9% by mass or less.

A concentration of the curable component in the composition for forming an underlayer film (including a solvent) is not particularly limited, but is preferably 0.01% by mass or higher, more preferably 0.05% by mass or higher, and still more preferably 0.1% by mass or higher. The upper limit thereof is preferably 10% by mass or lower, more preferably 5% by mass or lower, still more preferably 1% by mass or lower, and even more preferably less than 1% by mass.

<Resin>

As the resin in the composition for forming an underlayer film, well-known resins can be widely used. The resin used in the present invention preferably has at least one of a radically polymerizable group or a polar group, and more preferably has both a radically polymerizable group and a polar group.

By having the radically polymerizable group, an underlayer film having excellent hardness can be obtained. Moreover, by having a polar group, adhesiveness to a substrate is improved. Furthermore, in a case where a crosslinking agent is formulated, a crosslinking structure formed after curing is further firmed, and hardness of the obtained underlayer film can be improved.

The radically polymerizable group preferably includes a group having an ethylenically unsaturated bond. Examples of the group having an ethylenically unsaturated bond include a (meth)acryloyl group (preferably a (meth)acryloyloxy group and a (meth)acryloylamino group), a vinyl group, a vinyloxy group, an allyl group, a methylallyl group, a propenyl group, a butenyl group, a vinylphenyl group, and a cyclohexenyl group, a (meth)acryloyl group and a vinyl group are preferable, a (meth)acryloyl group is more preferable, and a (meth)acryloyloxy group is still more preferable. The group having an ethylenically unsaturated bond defined here is referred to as Et.

Furthermore, the polar group is preferably at least one kind of an acyloxy group, a carbamoyloxy group, a sulfonyloxy group, an acyl group, an alkoxycarbonyl group, an acylamino group, a carbamoyl group, an alkoxycarbonylamino group, a sulfonamide group, a phosphoric acid group, a carboxyl group, or a hydroxyl group, more preferably at least one kind of an alcoholic hydroxyl group, a phenolic hydroxyl group, or a carboxyl group, and still more preferably an alcoholic hydroxyl group or a carboxyl group. The polar group defined here is referred to as a polar group Po. The polar group is preferably a nonionic group.

The resin in the composition for forming an underlayer film may further contain a cyclic ether group. Examples of the cyclic ether group include an epoxy group and an oxetanyl group, and an epoxy group is preferable. The cyclic ether group defined here is referred to as a cyclic ether group Cyt.

Examples of the resin include a (meth)acrylic resin, a vinyl resin, a novolac resin, a phenol resin, a melamine resin, a urea resin, an epoxy resin, and a polyimide resin, and at least one kind of a (meth)acrylic resin, a vinyl resin, or a novolac resin is preferable.

A weight-average molecular weight of the resin is preferably 4,000 or greater, more preferably 6,000 or greater, and still more preferably 8,000 or greater. The upper limit thereof is preferably 1,000,000 or less and may be 500,000 or less.

The resin preferably has at least one of constitutional units represented by Formulae (1) to (3).

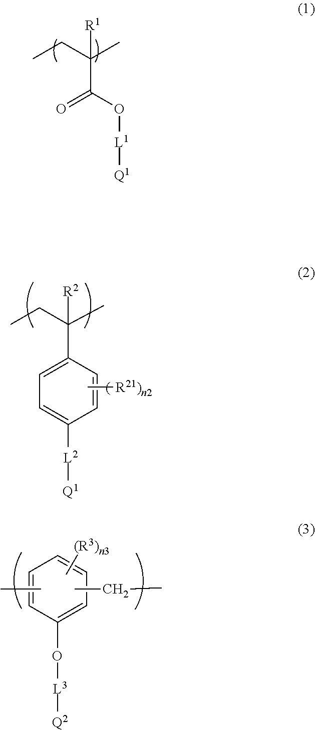

In the formulae, R¹ and R² are each independently a hydrogen atom or a methyl group. R²¹ and R³ are each independently a substituent. L¹, L², and L³ are each independently a single bond or a linking group. n2 is an integer of 0 to 4. n3 is an integer of 0 to 3. Q¹ is a group having an ethylenically unsaturated bond or a cyclic ether group. Q² is a group having an ethylenically unsaturated bond, a cyclic ether group, or a polar group.

R¹ and R² are each preferably a methyl group.

It is preferable that R²¹ and R³ are each independently the substituent T.

In a case where there are a plurality of R²¹'s, R²¹'s may be linked to each other to form a cyclic structure. In the present specification, the linking is meant to include not only an aspect in which groups are continued by bonding but also an aspect in which groups lose some atoms and are fused (condensed). Moreover, unless otherwise specified, an oxygen atom, a sulfur atom, and a nitrogen atom (amino group) may be included in the linking cyclic structure. Examples of the formed cyclic structure include an aliphatic hydrocarbon ring (groups exemplified below are referred to as a ring CO (for example, a cyclopropyl group, a cyclobutyl group, a cyclopentyl group, a cyclohexyl group, a cyclopropenyl group, a cyclobutenyl group, a cyclopentenyl group, a cyclohexenyl group, and the like), an aromatic hydrocarbon ring (rings exemplified below are referred to as a ring Cr) (a benzene ring, a naphthalene ring, an anthracene ring, a phenanthrene ring, and the like), a nitrogen-containing heterocycle (rings exemplified below are referred to as a ring Cn) (for example, a pyrrole ring, an imidazole ring, a pyrazole ring, a pyridine ring, a pyrroline ring, a pyrrolidine ring, an imidazolidine ring, a pyrazolidine ring, a piperidine ring, a piperazine ring, a morpholine ring, and the like), an oxygen-containing heterocycle (rings exemplified below are referred to as a ring Co) (a furan ring, a pyran ring, an oxirane ring, an oxetane ring, a tetrahydrofuran ring, a tetrahydropyran ring, a dioxane ring, and the like), and a sulfur-containing heterocycle (rings exemplified below are referred to as a ring Cs) (a thiophene ring, a thiirane ring, a thietane ring, a tetrahydrothiophene ring, a tetrahydrothiopyran ring, and the like).

In a case where there are a plurality of R³'s, R³'s may be linked to each other to form a cyclic structure. Examples of the formed cyclic structure include ring Cf, the ring Cr, the ring Cn, the ring Co, and the ring Cs.

It is preferable that L¹, L², and L³ are each independently a single bond or a linking group L described later. Among them, a single bond, or an alkylene group or an (oligo)alkyleneoxy group, which is defined as the linking group L, is preferable, and an alkylene group is more preferable. The linking group L preferably has the polar group Po as a substituent. Moreover, an aspect in which the alkylene group has a hydroxyl group as a substituent is also preferable.

n2 is preferably 0 or 1 and more preferably 0. n3 is preferably 0 or 1 and more preferably 0.

Q¹ is preferably the group Et having an ethylenically unsaturated bond.

Q² is preferably a polar group or preferably an alkyl group having an alcoholic hydroxyl group.

The resin may further contain at least one of a constitutional unit (11), a constitutional unit (21), or a constitutional unit (31). In particular, in the resin included in the present invention, the constitutional unit (11) is preferably combined with the constitutional unit (1), the constitutional unit (21) is preferably combined with the constitutional unit (2), and the constitutional unit (31) is preferably combined with the constitutional unit (3).

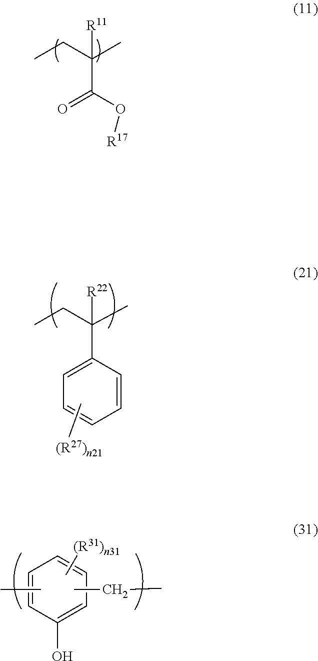

In the formulae, R¹¹ and R²² are each independently a hydrogen atom or a methyl group. R¹⁷ is a substituent. R²⁷ is a substituent. n21 is an integer of 0 to 5. R³¹ is a substituent, and n31 is an integer of 0 to 3.

R¹¹ and R²² are each preferably a methyl group.

R¹⁷ is preferably a group containing a polar group or a group containing a cyclic ether group. In a case where R¹⁷ is a group containing a polar group, R¹⁷ is preferably a group containing the polar group Po and more preferably the polar group Po or the substituent T substituted with the polar group Po. In a case where R¹⁷ is a group containing a cyclic ether group, R¹⁷ is preferably a group containing the cyclic ether group Cyt and more preferably the substituent T substituted with the cyclic ether group Cyt.

R²⁷ is a substituent, and at least one of R²⁷'s is preferably a polar group. The substituent is preferably the substituent T. n21 is preferably 0 or 1 and more preferably 0. In a case where there are a plurality of R²⁷'s, R²⁷'s may be linked to each other to form a cyclic structure. Examples of the formed cyclic structure include examples of the ring Cf, the ring Cr, the ring Cn, the ring Co, and the ring Cs.

R³¹ is preferably the substituent T. n31 is an integer of 0 to 3, preferably 0 or 1, and more preferably 0. In a case where there are a plurality of R³¹'s, R³¹'s may be linked to each other to form a cyclic structure. Examples of the formed cyclic structure include examples of the ring Cf, the ring Cr, the ring Cn, the ring Co, and the ring Cs.

Examples of the linking group L include an alkylene group (the number of the carbon atoms is preferably 1 to 24, more preferably 1 to 12, and still more preferably 1 to 6), an alkenylene group (the number of the carbon atoms is preferably 2 to 12, more preferably 2 to 6, and still more preferably 2 or 3), an (oligo)alkyleneoxy group (the number of carbon atoms in an alkylene group in one constitutional unit is preferably 1 to 12, more preferably 1 to 6, and still more preferably 1 to 3; and the number of repetitions is preferably 1 to 50, more preferably 1 to 40, and still more preferably 1 to 30), an arylene group (the number of the carbon atoms is preferably 6 to 22, more preferably 6 to 18, and still more preferably 6 to 10), an oxygen atom, a sulfur atom, a sulfonyl group, a carbonyl group, a thiocarbonyl group, —NR^{N}—, and a linking group related to a combination thereof. The alkylene group, alkenylene group, and alkyleneoxy group may have the substituent T. For example, the alkylene group may have a hydroxyl group.

A linking chain length of the linking group L is preferably 1 to 24, more preferably 1 to 12, and still more preferably 1 to 6. The linking chain length means the number of atoms positioned on the shortest path among the atomic groups involved in the linkage. For example, in a case of —CH₂—(C═O)—O—, the linking chain length is 3.

Furthermore, the alkylene group, alkenylene group, and (oligo)alkyleneoxy group, which are defined as the linking group L, may be chain-like or cyclic, or may be linear or branched.

It is preferable that as an atom constituting the linking group L, a carbon atom, a hydrogen atom, and if necessary, a heteroatom (at least one kind selected from an oxygen atom, a nitrogen atom, or a sulfur atom, and the like) are included. The number of carbon atoms in the linking group is preferably 1 to 24, more preferably 1 to 12, and still more preferably 1 to 6. The number of hydrogen atom may be determined according to the number of carbon atoms and the like. In a case of the number of heteroatoms, the numbers of the oxygen atoms, the nitrogen atoms, and the sulfur atoms are each independently preferably 0 to 12, more preferably 0 to 6, and still more preferably 0 to 3.

The resin may be synthesized by a conventional method. For example, a resin having the constitutional unit represented by Formula (1) can be appropriately synthesized by a well-known method for addition polymerization of olefin. A resin having the constitutional unit represented by Formula (2) can be appropriately synthesized by a well-known method for addition polymerization of styrene. A resin having the constitutional unit represented by Formula (3) can be appropriately synthesized by a well-known method for synthesis of a phenol resin.

One kind of the resins may be used, or a plurality thereof may be used.

As the resin as the curable component, in addition to the aforementioned resins, the resins described in paragraphs 0016 to 0079 of WO2016/152600A, paragraphs 0025 to 0078 of WO2016/148095A, paragraphs 0015 to 0077 of WO2016/031879A, and paragraphs 0015 to 0057 of WO2016/027843A can be used, the contents of which are incorporated in the present specification.

<Crosslinking Agent>

The crosslinking agent in the composition for forming an underlayer film is not particularly limited as long as the crosslinking agent advances curing by a crosslinking reaction. In the present invention, the crosslinking agent is preferably reacted with a polar group of a resin to form a crosslinking structure. By using such a crosslinking agent, the resin is more firmly bonded, and a firmer film can be obtained.

Examples of the crosslinking agent include an epoxy compound (compound having an epoxy group), an oxetanyl compound (compound having an oxetanyl group), an alkoxymethyl compound (compound having an alkoxymethyl group), a methylol compound (compound having a methylol group), and a blocked isocyanate compound (compound having a blocked isocyanate group), and an alkoxymethyl compound (compound having an alkoxymethyl group) can form a firm bond at a low temperature and thus is preferable.

<Other Components>

The composition for forming an underlayer film of the present invention may contain other components in addition to the aforementioned components.

Specifically, one or more kinds of a solvent, a thermal acid generator, an alkylene glycol compound, a polymerization initiator, a polymerization inhibitor, an antioxidant, a leveling agent, a thickener, a surfactant, or the like may be contained. Regarding the aforementioned components, the respective components described in JP2013-036027A, JP2014-090133A, and JP2013-189537A can be used. Also regarding the content or the like, reference can be made to the description in the aforementioned publications.

<<Solvent>>

In the present invention, the composition for forming an underlayer film particularly preferably contains a solvent (hereinafter, also referred to as a “solvent for an underlayer film”). For example, the solvent is preferably a compound which is liquid at 23° C. and has a boiling point of 250° C. or lower. A content of the solvent for an underlayer film in the composition for forming an underlayer film is preferably 99.0% by mass or greater and more preferably 99.2% by mass or greater, and may be 99.4% by mass or greater. That is, the concentration of the total solid content in the composition for forming an underlayer film is preferably 1% by mass or lower, more preferably 0.8% by mass or lower, and still more preferably 0.6% by mass or lower. Moreover, the lower limit value thereof is preferably higher than 0% by mass, more preferably 0.001% by mass or higher, still more preferably 0.01% by mass or higher, and even more preferably 0.1% by mass or higher. By setting the proportion of the solvent within the above range, a film thickness during film formation is kept thin, and thus pattern formability during etching processing tends to be improved.

Only one kind or two or more kinds of the solvents may be contained in the composition for forming an underlayer film. In a case where two or more kinds thereof are contained, the total amount thereof is preferably within the above range.

The boiling point of the solvent for an underlayer film is preferably 230° C. or lower, more preferably 200° C. or lower, still more preferably 180° C. or lower, even more preferably 160° C. or lower, and further still more preferably 130° C. or lower. The lower limit value thereof is practically 23° C. but more practically 60° C. or higher. By setting the boiling point within the above range, the solvent can be easily removed from the underlayer film, which is preferable.

The solvent for an underlayer film is preferably an organic solvent. The solvent is preferably a solvent having any one or more of an ester group, a carbonyl group, a hydroxyl group, or an ether group. Among them, an aprotic polar solvent is preferably used.

Examples of a preferred solvent among the solvents for an underlayer film include alkoxy alcohol, propylene glycol monoalkyl ether carboxylate, propylene glycol monoalkyl ether, lactate, acetate, alkoxypropionate, chain-like ketone, cyclic ketone, lactone, and alkylene carbonate, and propylene glycol monoalkyl ether and lactone are particularly preferable.

<<Thermal Acid Generator>>

The thermal acid generator is a compound which generates an acid by heating and advances crosslinking by the action of the acid. In a case of being used in combination with the crosslinking agent, an underlayer film having higher hardness can be obtained.

As the thermal acid generator, an organic onium salt compound in which a cationic component and an anionic component are paired is usually used. As the cationic component, for example, organic sulfonium, organic oxonium, organic ammonium, organic phosphonium, and organic iodonium can be mentioned. Moreover, as the anionic component, for example, BF⁴⁻, B(C₆F₅)⁴⁻, SbF⁶⁻, AsF⁶⁻, PF⁶⁻, CF₃SO₃⁻, C₄F₉SO₃⁻, and (CF₃SO₂)₃C⁻ can be mentioned.

Specifically, reference can be made to the description in paragraphs 0243 to 0256 of JP2017-224660A and paragraph 0016 of JP2017-155091A, the contents of which are incorporated in the present specification.

A content of the thermal acid generator is preferably 0.01 to 10 parts by mass and more preferably 0.1 to 5 parts by mass with respect to 100 parts by mass of the crosslinking agent. Only one kind or two or more kinds of the thermal acid generators may be used. In a case where two or more kinds thereof are used, the total amount thereof is preferably within the above range.

<<Polymerization Initiator>>

The composition for forming an underlayer film may contain a polymerization initiator and preferably contains at least one kind of a thermal polymerization initiator or a photopolymerization initiator. By containing the polymerization initiator, a reaction of a polymerizable group contained in the composition for forming an underlayer film is promoted, and thus the adhesiveness tends to be improved. From the viewpoint that crosslinking reactivity with the curable composition is improved, a photopolymerization initiator is preferable. As the photopolymerization initiator, a radical polymerization initiator and a cationic polymerization initiator are preferable, and a radical polymerization initiator is more preferable. Moreover, in the present invention, a plurality of kinds of photopolymerization initiators may be used in combination.

As a photoradical polymerization initiator, well-known compounds can be optionally used. Examples thereof include a halogenated hydrocarbon derivative (for example, a compound having a triazine skeleton, a compound having an oxadiazole skeleton, a compound having a trihalomethyl group, and the like), an acylphosphine compound such as acylphosphine oxide, hexaarylbiimidazole, an oxime compound such as an oxime derivative, an organic peroxide, a thio compound, a ketone compound, an aromatic onium salt, ketoxime ether, an aminoacetophenone compound, hydroxyacetophenone, an azo-based compound, an azide compound, a metallocene compound, an organic boron compound, and an iron arene complex. For the details thereof, reference can be made to the description in paragraphs 0165 to 0182 of JP2016-027357A, the contents of which are incorporated in the present specification.

Examples of the acylphosphine compound include 2,4,6-trimethylbenzoyl-diphenyl-phosphine oxide. Moreover, IRGACURE-819, IRGACURE 1173, and IRGACURE-TPO (trade names: all are produced by BASF SE), which are commercially available products, can be used.

In a case where the photopolymerization initiator used in the composition for forming an underlayer film is formulated, a content thereof in the total solid content is, for example, 0.0001% to 5% by mass, preferably 0.0005% to 3% by mass, and more preferably 0.01% to 1% by mass. In a case where two or more kinds of photopolymerization initiators are used, the total amount thereof is within the above range.

[Composition for Forming Liquid Film]

In addition, in the present invention, it is also preferable that a liquid film is formed on the underlayer film by using a composition for forming a liquid film containing a polymerizable compound which is a liquid at 23° C. and 1 atm. In the present invention, the liquid film can be obtained by applying the composition for forming a liquid film onto the substrate and then drying the composition, in the same manner as the curable composition. By forming such a liquid film, there is an effect that the adhesiveness between the substrate and the curable composition is further improved, and the wettability of the curable composition on the substrate is also improved. Hereinafter, the composition for forming a liquid film will be described.

The viscosity of the composition for forming a liquid film is preferably 1,000 mPa·s or lower, more preferably 800 mPa·s or lower, still more preferably 500 mPa·s or lower, and even more preferably 100 mPa·s or lower. The lower limit value of the viscosity is not particularly limited, but can be, for example, 1 mPa·s or higher. The viscosity is measured according to the following method.

The viscosity is measured using an E-type rotational viscometer RE85L manufactured by TOM SANGYO CO., LTD. and a standard cone rotor (1° 34′×R24) in a state where a temperature of a sample cup is adjusted to 23° C. The unit is mPa·s. Other details regarding the measurement are in accordance with JIS Z 8803:2011. Two samples are produced for one level and are respectively measured three times. An arithmetic mean value of a total of six times is adopted as an evaluation value.

<Polymerizable compound A>

The composition for forming a liquid film contains a polymerizable compound (polymerizable compound A) which is a liquid at 23° C. and 1 atm.

A viscosity of the polymerizable compound A at 23° C. is preferably 1 to 100,000 mPa·s. The lower limit thereof is preferably 5 mPa·s or higher and more preferably 11 mPa·s or higher. The upper limit thereof is preferably 1,000 mPa·s or lower and more preferably 600 mPa·s or lower.

The polymerizable compound A may be a monofunctional polymerizable compound having only one polymerizable group in one molecule, or a polyfunctional polymerizable compound having two or more polymerizable groups in one molecule. The monofunctional polymerizable compound and the polyfunctional polymerizable compound may be used in combination. Among them, for a reason of suppressing pattern collapse, the polymerizable compound A contained in the composition for forming a liquid film preferably includes a polyfunctional polymerizable compound, more preferably includes a polymerizable compound having two to five polymerizable groups in one molecule, still more preferably includes a polymerizable compound having two to four polymerizable groups in one molecule, and particularly preferably includes a polymerizable compound having two polymerizable groups in one molecule.

Furthermore, the polymerizable compound A preferably contains at least one of an aromatic ring (the number of the carbon atoms is preferably 6 to 22, more preferably 6 to 18, and still more preferably 6 to 10) or an alicyclic ring (the number of the carbon atoms is preferably 3 to 24, more preferably 3 to 18, and still more preferably 3 to 6), and more preferably contains an aromatic ring. The aromatic ring is preferably a benzene ring. Moreover, a molecular weight of the polymerizable compound A is preferably 100 to 900.

Examples of the polymerizable group of the polymerizable compound A include groups having an ethylenically unsaturated bond, such as a vinyl group, an allyl group, and a (meth)acryloyl group, and a (meth)acryloyl group is preferable.

It is also preferable that the polymerizable compound A is a compound represented by Formula (I-1).

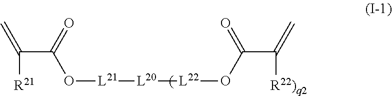

L²⁰ is a (1+q2)-valent linking group, and examples thereof include a (1+q2)-valent group (the number of the carbon atoms is preferably 1 to 12, more preferably 1 to 6, and still more preferably 1 to 3) having an alkane structure, a (1+q2)-valent group (the number of the carbon atoms is preferably 2 to 12, more preferably 2 to 6, and still more preferably 2 or 3) having an alkene structure, a (1+q2)-valent group (the number of the carbon atoms is preferably 6 to 22, more preferably 6 to 18, and still more preferably 6 to 10) having an aryl structure, a (1+q2)-valent group (the number of the carbon atoms is preferably 1 to 22, more preferably 1 to 18, and still more preferably 1 to 10, examples of a heteroatom include a nitrogen atom, a sulfur atom, and an oxygen atom, and a 5-membered ring, a 6-membered ring, and a 7-membered ring are preferable) having a heteroaryl structure, and a linking group including a group obtained by combining these groups. Examples of the group in which two aryl groups are combined include groups having a structure such as biphenyl, diphenylalkane, biphenylene, and indene. Examples of a combination of the group having a heteroaryl structure and the group having an aryl structure include groups having a structure such as indole, benzimidazole, quinoxaline, and carbazole.

L²⁰ is preferably a linking group including at least one kind selected from a group having an aryl structure or a group having a heteroaryl structure, and more preferably a linking group including a group having an aryl structure.

R²¹ and R²² each independently represent a hydrogen atom or a methyl group.

L²¹ and L²² each independently represent a single bond or the linking group L, and a single bond or an alkylene group is preferable.

L²⁰ and L²¹ or L²² may be bonded to each other via or without via the linking group L may be bonded to each other to form a ring. In a case where there are the plurality of substituents T, the plurality of substituents T may be the same as or different from each other.

q2 is an integer of 0 to 5, preferably an integer of 0 to 3, more preferably an integer of 0 to 2, still more preferably 0 or 1, and particularly preferably 1.

As the polymerizable compound A, the compounds described in paragraphs 0017 to 0024 and Examples of JP2014-090133A, the compounds described in paragraphs 0024 to 0089 of JP2015-009171A, the compounds described in paragraphs 0023 to 0037 of JP2015-070145A, and the compounds described in paragraphs 0012 to 0039 of WO2016/152597A can also be used.

A content of the polymerizable compound A in the composition for forming a liquid film is preferably 0.01% by mass or greater, more preferably 0.05% by mass or greater, and still more preferably 0.1% by mass or greater. The upper limit thereof is preferably 10% by mass or less, more preferably 5% by mass or less, and still more preferably 1% by mass or less.

The content of the polymerizable compound A in a non-volatile component (refers to components other than a solvent in the composition, hereinafter, the same applies) of the composition for forming a liquid film is preferably 50% by mass or greater, more preferably 75% by mass or greater, and still more preferably 90% by mass or greater. The upper limit thereof may be 100% by mass. Only one kind of the polymerizable compounds A may be used, or two or more kinds thereof may be used. In a case where two or more kinds thereof are used, the total amount thereof is preferably within the above range.

Furthermore, it is also preferable that the non-volatile component of the composition for forming a liquid film substantially consists of the polymerizable compound A. The case where the non-volatile component of the composition for forming a liquid film substantially consists of the polymerizable compound A means that the content of the polymerizable compound A in the non-volatile component of the composition for forming a liquid film is 99.9% by mass or greater, the content is more preferably 99.99% by mass or greater, and it is still more preferable that the non-volatile component consists of the polymerizable compound A.

<Solvent>

The composition for forming a liquid film preferably contains a solvent (hereinafter, referred to as a “solvent for a liquid film” in some cases). Examples of the solvent for a liquid film include the solvents described in the aforementioned section of the solvent for an underlayer film, and these solvents can be used. A content of the solvent for a liquid film in the composition for forming a liquid film is preferably 90% by mass or greater and more preferably 99% by mass or greater, and may be 99.99% by mass or greater.

The boiling point of the solvent for a liquid film is preferably 230° C. or lower, more preferably 200° C. or lower, still more preferably 180° C. or lower, even more preferably 160° C. or lower, and further still more preferably 130° C. or lower. The lower limit value thereof is practically 23° C. but more practically 60° C. or higher. By setting the boiling point within the above range, the solvent can be easily removed from the liquid film, which is preferable.

<Radical Polymerization Initiator>

The composition for forming a liquid film may contain a radical polymerization initiator. Examples of the radical polymerization initiator include a thermal radical polymerization initiator and a photoradical polymerization initiator, and a photoradical polymerization initiator is preferable. As a photoradical polymerization initiator, well-known compounds can be optionally used. Examples thereof include a halogenated hydrocarbon derivative (for example, a compound having a triazine skeleton, a compound having an oxadiazole skeleton, a compound having a trihalomethyl group, and the like), an acylphosphine compound, a hexaarylbiimidazole compound, an oxime compound, an organic peroxide, a thio compound, a ketone compound, an aromatic onium salt, an acetophenone compound, an azo compound, an azide compound, a metallocene compound, an organic boron compound, and an iron arene complex. For the details thereof, reference can be made to the description in paragraphs 0165 to 0182 of JP2016-027357A, the contents of which are incorporated in the present specification. Among them, an acetophenone compound, an acylphosphine compound, and an oxime compound are preferable. Examples of a commercially available product thereof include IRGACURE-OXE01, IRGACURE-OXE02, IRGACURE-127, IRGACURE-819, IRGACURE-379, IRGACURE-369, IRGACURE-754, IRGACURE-1800, IRGACURE-651, IRGACURE-907, IRGACURE-TPO, and IRGACURE-1173 (all produced by BASF SE), and Omnirad 184, Omnirad TPO H, Omnirad 819, and Omnirad 1173 (all produced by IGM Resins B.y.).

In a case where the radical polymerization initiator is contained, the content thereof with respect to the non-volatile component of the composition for forming a liquid film is preferably 0.1% to 10% by mass, more preferably 1% to 8% by mass, and still more preferably 2% to 5% by mass. In a case where two or more kinds of the radical polymerization initiators are used, the total amount thereof is preferably within the above range.

<Other Components>

The composition for forming a liquid film may contain one or more kinds of a polymerization inhibitor, an antioxidant, a leveling agent, a thickener, a surfactant, or the like, in addition to the aforementioned components.

[Kit]

A kit according to the embodiment of the present invention includes the curable composition for forming a pattern (cured film) for imprinting, and a composition for forming an underlayer film, which is for forming an underlayer film for imprinting. By using the kit according to the embodiment of the present invention, imprinting having excellent releasability can be performed. The composition for forming an underlayer film particularly preferably contains the resin having a radically polymerizable group, and an organic solvent. Furthermore, the kit according to the embodiment of the present invention preferably contains a composition for forming a liquid film containing a polymerizable compound which is a liquid at 23° C. and 1 atm.

### EXAMPLES

Hereinafter, the present invention will be described in more detail with reference to Examples. The materials, the used amounts, the ratios, the treatment details, the treatment procedures, and the like shown in the following Examples can be appropriately modified without departing from the spirit of the present invention. Therefore, the scope of the present invention is not limited to the specific examples described below. In Examples, unless otherwise specified, various treatments were performed in an environment of 23° C.

<Preparation of Curable Composition>

Respective materials were formulated and mixed so as to satisfy each of formulation ratios (parts by mass) shown in Tables 1 to 3. After the mixing, the mixture was subjected to two-stage filtration with a Nylon filter having a pore diameter of 0.02 μm and an ultra-high-molecular-weight polyethylene (UPE) filter having a pore diameter of 0.003 μm to prepare curable compositions V-1 to V-26 (Examples) and R-1 to R-3 (Comparative Examples). Here, all of Comparative Examples R-1 to R-3 are examples of compositions containing no compound C, and in particular, in Comparative Examples R-2 and R-3, additives H-1 and H-2 were respectively added as comparison targets of the compound C. The specific specifications of each material are as follows.

TABLE 1

| | | Composition | Composition | Composition | Composition | Composition |
|---|---|---|---|---|---|---|
| | | V-1 | V-2 | V-3 | V-4 | V-5 |
| Compound C | C-1 | 3.000 | | | | |
| | C-2 | | 3.000 | | | |
| | C-3 | | | 3.000 | | |
| | C-4 | | | | 3.000 | |
| | C-5 | | | | | 3.000 |
| | C-6 | | | | | |
| | C-7 | | | | | |
| | C-8 | | | | | |
| | C-9 | | | | | |
| | C-10 | | | | | |
| | C-11 | | | | | |
| | C-12 | | | | | |
| | C-13 | | | | | |
| | C-14 | | | | | |
| | C-15 | | | | | |
| | C-16 | | | | | |
| | C-17 | | | | | |
| | C-18 | | | | | |
| Polymerizable | P-1 | 70.000 | 70.000 | 70.000 | 70.000 | 70.000 |
| compound | P-2 | 21.980 | 21.980 | 21.980 | 21.980 | 21.980 |
| | P-3 | | | | | |
| | P-4 | | | | | |
| | P-5 | | | | | |
| | P-6 | | | | | |
| | P-7 | | | | | |
| | P-8 | | | | | |
| Radical | PI-1 | 3.000 | 3.000 | 3.000 | 3.000 | 3.000 |
| polymerization | PI-2 | | | | | |
| initiator | PI-3 | | | | | |
| | PI-4 | | | | | |
| Release agent | RL-1 | 2.000 | 2.000 | 2.000 | 2.000 | 2.000 |
| | RL-2 | | | | | |
| | RL-3 | | | | | |
| Additive | H-1 | | | | | |
| | H-2 | | | | | |
| | AD-1 | 0.010 | 0.010 | 0.010 | 0.010 | 0.010 |
| | AD-2 | 0.010 | 0.010 | 0.010 | 0.010 | 0.010 |
| | AD-3 | | | | | |
| Content of | | 3.000 | 3.000 | 3.000 | 3.000 | 3.000 |
| compound C with | | | | | | |
| respect to entire | | | | | | |
| composition | | | | | | |
| Content of | | 3.262 | 3.262 | 3.262 | 3.262 | 3.262 |
| compound C with | | | | | | |
| respect to total | | | | | | |
| polymerizable | | | | | | |
| compound | | | | | | |
| | | Composition | Composition | Composition | Composition | Composition |
| | | V-6 | V-7 | V-8 | V-9 | V-10 |
| Compound C | C-1 | | 15.000 | 0.008 | 94.980 | 3.000 |
| | C-2 | | | | | |
| | C-3 | | | | | |
| | C-4 | | | | | |
| | C-5 | | | | | |
| | C-6 | 3.000 | | | | |
| | C-7 | | | | | |
| | C-8 | | | | | |
| | C-9 | | | | | |
| | C-10 | | | | | |
| | C-11 | | | | | |
| | C-12 | | | | | |
| | C-13 | | | | | |
| | C-14 | | | | | |
| | C-15 | | | | | |
| | C-16 | | | | | |
| | C-17 | | | | | |
| | C-18 | | | | | |
| Polymerizable | P-1 | 70.000 | 58.000 | 72.992 | | |
| compound | P-2 | 21.980 | 21.980 | 21.980 | | 70.000 |
| | P-3 | | | | | |
| | P-4 | | | | | |
| | P-5 | | | | | |
| | P-6 | | | | | |
| | P-7 | | | | | |
| | P-8 | | | | | 21.980 |
| Radical | PI-1 | 3.000 | 3.000 | 3.000 | 3.000 | 3.000 |
| polymerization | PI-2 | | | | | |
| initiator | PI-3 | | | | | |
| | PI-4 | | | | | |
| Release agent | RL-1 | 2.000 | 2.000 | 2.000 | 2.000 | 2.000 |
| | RL-2 | | | | | |
| | RL-3 | | | | | |
| Additive | H-1 | | | | | |
| | H-2 | | | | | |
| | AD-1 | 0.010 | 0.010 | 0.010 | 0.010 | 0.010 |
| | AD-2 | 0.010 | 0.010 | 0.010 | 0.010 | 0.010 |
| | AD-3 | | | | | |

| | | | | | |
|---|---|---|---|---|---|
| Content of | 3.000 | 15.000 | 0.008 | 94.980 | 3.000 |
| compound C with | | | | | |
| respect to entire | | | | | |
| composition | | | | | |
| Content of | 3.262 | 18.755 | 0.008 | #DIV/0! | 3.262 |
| compound C with | | | | | |
| respect to total | | | | | |
| polymerizable | | | | | |
| compound | | | | | |

TABLE 2

| | | Composition | Composition | Composition | Composition | Composition |
|---|---|---|---|---|---|---|
| | | V-11 | V-12 | V-13 | V-14 | V-15 |
| Compound C | C-1 | 26.000 | 3.000 | 3.000 | 3.000 | |
| | C-2 | | | | | |
| | C-3 | | | | | |
| | C-4 | | | | | |
| | C-5 | | | | | |
| | C-6 | | | | | |
| | C-7 | | | | | 3.000 |
| | C-8 | | | | | |
| | C-9 | | | | | |
| | C-10 | | | | | |
| | C-11 | | | | | |
| | C-12 | | | | | |
| | C-13 | | | | | |
| | C-14 | | | | | |
| | C-15 | | | | | |
| | C-16 | | | | | |
| | C-17 | | | | | |
| | C-18 | | | | | |
| Polymerizable | P-1 | 40.000 | 70.000 | 72.000 | 70.000 | 70.000 |
| compound | P-2 | 30.000 | 21.980 | 21.980 | 21.980 | 21.980 |
| | P-3 | | | | | |
| | P-4 | | | | | |
| | P-5 | | | | | |
| | P-6 | | | | | |
| | P-7 | | | | | |
| | P-8 | | | | | |
| Radical | PI-1 | 3.000 | | | 3.000 | 1.000 |
| polymerization | PI-2 | | | | | 1.000 |
| initiator | PI-3 | | | | | 1.000 |
| | PI-4 | | 3.000 | 3.000 | | |
| Release agent | RL-1 | 0.980 | 2.000 | | | 2.000 |
| | RL-2 | | | | | |
| | RL-3 | | | | 2.000 | |
| Additive | H-1 | | | | | |
| | H-2 | | | | | |
| | AD-1 | 0.010 | 0.010 | 0.010 | 0.010 | 0.010 |
| | AD-2 | 0.010 | 0.010 | 0.010 | 0.010 | 0.010 |
| | AD-3 | | | | | |
| Content of | | 26.000 | 3.000 | 3.000 | 3.000 | 3.000 |
| compound C with | | | | | | |
| respect to entire | | | | | | |
| composition | | | | | | |
| Content of | | 37.143 | 3.262 | 3.192 | 3.262 | 3.262 |
| compound C with | | | | | | |
| respect to total | | | | | | |
| polymerizable | | | | | | |
| compound | | | | | | |
| | | Composition | Composition | Composition | Composition | Composition |
| | | V-16 | V-17 | V-18 | V-19 | V-20 |
| Compound C | C-1 | | | | | |
| | C-2 | | | | | |
| | C-3 | | | | | |
| | C-4 | | | | | |
| | C-5 | | | | | |
| | C-6 | | | | | |
| | C-7 | | | | | |
| | C-8 | 3.000 | | | | |
| | C-9 | | 3.000 | | | |
| | C-10 | | | 3.000 | | |
| | C-11 | | | | 3.000 | |
| | C-12 | | | | | 3.000 |
| | C-13 | | | | | |
| | C-14 | | | | | |
| | C-15 | | | | | |
| | C-16 | | | | | |
| | C-17 | | | | | |
| | C-18 | | | | | |
| Polymerizable | P-1 | 70.000 | 70.000 | 70.000 | 35.000 | |
| compound | P-2 | 21.980 | 21.980 | | 21.980 | 21.980 |
| | P-3 | | | | 35.000 | 70.000 |
| | P-4 | | | | | |
| | P-5 | | | | | |
| | P-6 | | | | | |
| | P-7 | | | | | |
| | P-8 | | | 21.980 | | |
| Radical | PI-1 | 3.000 | 3.000 | 3.000 | 3.000 | 3.000 |
| polymerization | PI-2 | | | | | |
| initiator | PI-3 | | | | | |
| | PI-4 | | | | | |
| Release agent | RL-1 | 2.000 | 2.000 | 2.000 | 2.000 | 2.000 |
| | RL-2 | | | | | |
| | RL-3 | | | | | |
| Additive | H-1 | | | | | |
| | H-2 | | | | | |
| | AD-1 | 0.010 | 0.010 | 0.010 | 0.010 | 0.010 |
| | AD-2 | 0.010 | 0.010 | 0.010 | 0.010 | |
| | AD-3 | | | | | 0.010 |

| | | | | | |
|---|---|---|---|---|---|
| Content of | 3.000 | 3.000 | 3.000 | 3.000 | 3.000 |
| compound C with | | | | | |
| respect to entire | | | | | |
| composition | | | | | |
| Content of | 3.262 | 3.262 | 3.262 | 3.262 | 3.262 |
| compound C with | | | | | |
| respect to total | | | | | |
| polymerizable | | | | | |
| compound | | | | | |

TABLE 3

| | | Composition | Composition | Composition | Composition | Composition |
|---|---|---|---|---|---|---|
| | | V-21 | V-22 | V-23 | V-24 | V-25 |
| Compound C | C-1 | | | | | |
| | C-2 | | | | | |
| | C-3 | | | | | |
| | C-4 | | | | | |
| | C-5 | | | | | |
| | C-6 | | | | | |
| | C-7 | | | | | |
| | C-8 | | | | | |
| | C-9 | | | | | |
| | C-10 | | | | | |
| | C-11 | | | | | |
| | C-12 | | | | | |
| | C-13 | 3.000 | | | | |
| | C-14 | | 3.000 | | | |
| | C-15 | | | 3.000 | | |
| | C-16 | | | | 3.000 | |
| | C-17 | | | | | 3.000 |
| | C-18 | | | | | |
| Polymerizable | P-1 | 50.000 | | 50.000 | 70.000 | 70.000 |
| compound | P-2 | 21.980 | 21.980 | 21.980 | 21.980 | 21.980 |
| | P-3 | 10.000 | | 10.000 | | |
| | P-4 | 5.000 | | | | |
| | P-5 | 5.000 | | | | |
| | P-6 | | 35.000 | | | |
| | P-7 | | 35.000 | 10.000 | | |
| | P-8 | | | | | |
| Radical | PI-1 | 3.000 | 1.500 | 1.000 | 3.000 | 3.000 |
| polymerization | PI-2 | | 1.500 | 1.000 | | |
| initiator | PI-3 | | | 0.500 | | |
| | PI-4 | | | 0.500 | | |
| Release agent | RL-1 | 2.000 | | 2.000 | 1.000 | 1.000 |
| | RL-2 | | 2.000 | | | 1.000 |
| RL-3 | | | | 1.000 | | |
| Additive | H-1 | | | | | |
| | H-2 | | | | | |
| | AD-1 | 0.010 | 0.010 | | | |
| | AD-2 | 0.010 | 0.010 | 0.010 | 0.010 | |
| | AD-3 | | | | | |
| Content of compound C | | 3.000 | 3.000 | 3.000 | 3.000 | 3.001 |
| composition | | | | | | |
| with respect to entire | | | | | | |
| Content of compound C | | 3.262 | 3.262 | 3.262 | 3.262 | 3.262 |
| with respect to total | | | | | | |
| polymerizable | | | | | | |
| compound | | | | | | |
| | | | Composition | Composition | Composition | Composition |
| | | | V-26 | R-1 | R-2 | R-3 |
| | Compound C | C-1 | | | | |
| | | C-2 | | | | |
| | | C-3 | | | | |
| | | C-4 | | | | |
| | | C-5 | | | | |
| | | C-6 | | | | |
| | | C-7 | | | | |
| | | C-8 | | | | |
| | | C-9 | | | | |
| | | C-10 | | | | |
| | | C-11 | | | | |
| | | C-12 | | | | |
| | | C-13 | | | | |
| | | C-14 | | | | |
| | | C-15 | | | | |
| | | C-16 | | | | |
| | | C-17 | | | | |
| | | C-18 | 1.500 | | | |
| | Polymerizable | P-1 | 70.000 | 73.000 | 70.000 | 70.000 |
| | compound | P-2 | 21.980 | 21.980 | 21.980 | 21.980 |
| | | P-3 | | | | |
| | | P-4 | | | | |
| | | P-5 | | | | |
| | | P-6 | | | | |
| | | P-7 | | | | |
| | | P-8 | | | | |
| | Radical | PI-1 | 3.000 | 3.000 | 3.000 | 3.000 |
| | polymerization | PI-2 | | | | |
| | initiator | PI-3 | | | | |
| | | PI-4 | | | | |
| | Release agent | RL-1 | 2.000 | 2.000 | 2.000 | 2.000 |
| | | RL-2 | | | | |
| | | RL-3 | | | | |
| | Additive | H-1 | 1.500 | | 3.000 | |
| | | H-2 | | | | 3.000 |
| | | AD-1 | 0.010 | 0.010 | 0.010 | 0.010 |
| | | AD-2 | 0.010 | 0.010 | 0.010 | 0.010 |
| | | AD-3 | | | | |

| | | | | |
|---|---|---|---|---|
| Content of compound C | 1.500 | 0.000 | 0.000 | 0.000 |
| composition | | | | |
| with respect to entire | | | | |
| Content of compound C | 1.631 | 0.000 | 0.000 | 0.000 |
| with respect to total | | | | |
| polymerizable | | | | |
| compound | | | | |

<<Compound C>>

C-1 to C-18: Compounds C-1 to C-18 exemplified in the description of the compound C.

<<Compound for Comparison to Compound C>>

H-1 and H-2: Compounds having the following structures.

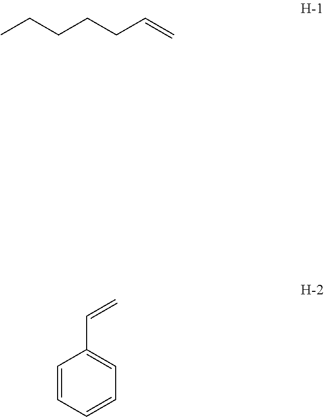

<<Polymerizable Compound>>

P-1: Neopentylglycol diacrylate (produced by KYOEISHA CHEMICAL Co., LTD.).

P-2: Benzyl acrylate (OSAKA ORGANIC CHEMICAL INDUSTRY LTD.).

P-3: Compound having the following structure.

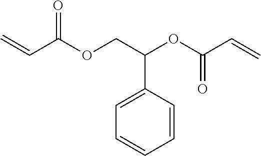 [SMILES: C=CC(=O)OCC(OC(=O)C=C)c1ccccc1]

P-4: (2-Methyl-2-ethyl-1,3-dioxolane-4-yl)methyl acrylate (produced by OSAKA ORGANIC CHEMICAL INDUSTRY LTD.).

P-5: Hexanediol diacrylate (produced by OSAKA ORGANIC CHEMICAL INDUSTRY LTD.).

P-6: Phenylethylene glycol diacrylate.

P-7: 2-Phenylpropane-1,3-diyl diacrylate.

P-8: 1-Acryloyloxy-3-hydroxyadamantane (produced by Tokyo Chemical Industry Co., Ltd.).

<<Radical Polymerization Initiator>>

PI-1: Lucirin TPO (produced by BASF SE).

PI-2: Omnirad 369 (produced by IGM Resins RV).

PI-3: Omnirad 651 (produced by IGM Resins RV).

PI-4: V-601 (produced by FUJIFILM Wako Pure Chemical Corporation).

<<Release Agent>>

RL-1: BLAUNON SR-705 (produced by AOKI OIL INDUSTRIAL Co., Ltd.).

RL-2: Pentadecaethylene glycol mono-1H,1H,2H,2H-perfluorooctyl ether (produced by DIC CORPORATION).

RL-3: ORGATIX SIC-330 (produced by Matsumoto Fine Chemical Co., Ltd.).

<<Additive>>

AD-1: 4,4′-bis(dimethylamino)benzophenone (produced by Tokyo Chemical Industry Co., Ltd.).

AD-2: Butylhydroxytoluene (BHT) (produced by Tokyo Chemical Industry Co., Ltd.).

AD-3: 4-Hydroxy-2,2,6,6-tetramethylpiperidine-1-oxyl free radical (4-hydroxy-TEMPO, produced by Tokyo Chemical Industry Co., Ltd.).

<Preparation of Composition for Forming Underlayer Film>

Respective materials were formulated and mixed so as to satisfy a formulation ratio shown in Table 4. After the mixing, the mixture was subjected to two-stage filtration with a Nylon filter having a pore diameter of 0.02 μm and an ultra-high-molecular-weight polyethylene (UPE) filter having a pore diameter of 0.003 μm to prepare compositions U-1 to U-4 for forming an underlayer film. The specific specifications of each material are as follows.

TABLE 4

| | Composition | Composition | Composition | Composition |
|---|---|---|---|---|
| | U-1 | U-2 | U-3 | U-4 |
| PU-1 | 0.5 | | | |
| PU-2 | | 0.5 | | |
| PU-3 | | | 0.5 | |
| PU-4 | | | | 0.5 |
| PGMEA | 99.5 | 99.5 | 99.5 | 99.5 |

PU-1: Compound containing the following two repeating units (Isorad501, SI Group, Inc.).

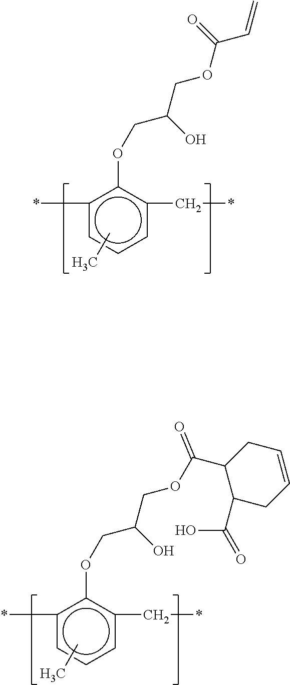

PU-2: Compound having the following structure (NK OLIGO EA-7440, produced by SHIN-NAKAMURA CHEMICAL CO, LTD.).

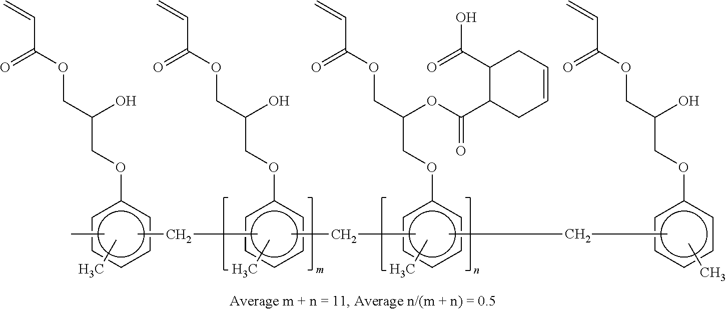

PU-3: Compound having the following structure synthesized by the following method.

PU-3 synthesis method: 80 g of ethyl acetate was added to a four-neck flask equipped with a stirring rod, a thermometer, a dropwise addition line, and a nitrogen/air mixed gas introducing pipe, and a temperature was raised to 40° C. After raising the temperature, 128 g of 2-(2-vinyloxyethoxy)ethyl acrylate (VEEA) and a mixed dissolved matter of 13g of ethyl acetate and 13 mg of phosphotungstic acid were added dropwise over 2 hours to allow a polymerization reaction to proceed. After completion of the polymerization, triethylamine was added to complete the reaction. Subsequently, concentration was performed with an evaporator to obtain a polymer PU-3 having the following structure. In the obtained polymer PU-3, the number-average molecular weight (Mn) was 9,900, and the molecular weight distribution (Mw/Mn) was 1.99.

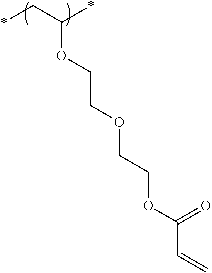

PU-4: Compound having the following structure. A ratio of respective repeating units is 40/30/30 in terms of molar ratio.

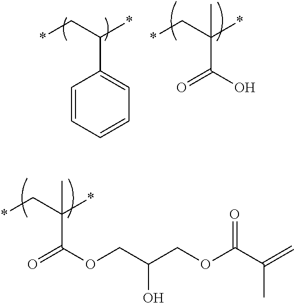

PGMEA: Propylene glycol monomethyl ether acetate.

<Preparation of Composition for Forming Liquid Film>

Respective materials were formulated and mixed so as to satisfy a formulation ratio shown in Table 5. After the mixing, the mixture was subjected to two-stage filtration with a Nylon filter having a pore diameter of 0.02 μm and an ultra-high-molecular-weight polyethylene (UPE) filter having a pore diameter of 0.003 μm to prepare a composition L-1 for forming a liquid film.

TABLE 5

| | Composition L-1 |
|---|---|
| P-3 | 0.03 |
| AD-2 | 0.003 |
| PGMEA | 99.967 |

<Evaluation of Releasability>

As the mold, a quartz mold with a 1:1 line/space pattern having a line width of 20 nm and a depth of 55 nm was used. A silicon wafer was spin-coated with the composition for forming an underlayer film, and heated for 1 minute using a hot plate at 220° C. to form an underlayer film having a thickness of 5 nm. The curable composition was applied onto the wafer (onto the underlayer film) by the ink jet method using an ink jet printer DMP-2831 manufactured by FUJIFILM Dimatix Inc., and then the curable composition was sandwiched between the silicon wafer and the mold under a helium atmosphere. After exposure was performed from the quartz mold side using a high-pressure mercury lamp under a condition of 100 mJ/cm², the quartz mold was released to obtain a pattern. Moreover, in Example 26, a liquid film having a thickness of 5 nm was formed before applying the curable composition. This liquid film was formed by spin-coating the surface of the underlayer film with the composition for forming a liquid film, heating the composition for 1 minute on a hot plate at 100° C., and drying the composition.

In the pattern formation, a force (releasing force F, unit: N) required for release in a case where the quartz mold was released was measured, and the releasability was evaluated as follows according to the measured value. The releasing force was measured according to the method described in paragraphs 0102 to 0107 of JP2011-206977A.
A: F≤15 N
B: 15 N<F≤18 N
C: 18 N<F≤20 N

<Evaluation of Pattern Collapse>

After the mold was peeled off, the pattern was observed with a scanning electron microscope, and evaluation was performed according to the following criteria. The observation of the pattern was performed at a magnification of 200,000 at a total of 15 points, such as the center and edge of a pattern forming region and a midpoint between the center and the edge, each of which was 1 μm square.
A: Pattern collapse and chipping of the pattern edge were not observed.
B: Pattern collapse was not observed, but chipping of the pattern edge was observed.
C: Pattern collapse was observed in a part or in a whole part.

<Evaluation Result>

The evaluation results of the respective Examples and Comparative Examples are shown in Table 6. From the results, it was found that the present invention containing the compound C can suppress the pattern collapse. Moreover, the present invention does not interfere with the use of the release agent. That is, the present invention is useful in that both the pattern collapse and the releasability can be further improved by containing both the compound C and the release agent.

TABLE 6

| | Curable | Liquid | Underlayer | Pattern | |
|---|---|---|---|---|---|
| | composition | film | film | collapse | Releasability |
| Example 1 | V-1 | — | U-1 | A | A |
| Example 2 | V-2 | — | U-1 | B | A |
| Example 3 | V-3 | — | U-1 | A | A |
| Example 4 | V-4 | — | U-1 | A | A |
| Example 5 | V-5 | — | U-1 | A | A |
| Example 6 | V-6 | — | U-1 | B | A |
| Example 7 | V-7 | — | U-1 | A | A |
| Example 8 | V-8 | — | U-1 | B | A |
| Example 9 | V-9 | — | U-1 | B | A |
| Example 10 | V-10 | — | U-1 | A | A |
| Example 11 | V-11 | — | U-1 | B | A |
| Example 12 | V-12 | — | U-1 | A | A |
| Example 13 | V-13 | — | U-1 | A | B |
| Example 14 | V-14 | — | U-1 | A | A |
| Example 15 | V-15 | — | U-1 | A | A |
| Example 16 | V-16 | — | U-1 | A | A |
| Example 17 | V-17 | — | U-1 | A | A |
| Example 18 | V-18 | — | U-1 | A | A |
| Example 19 | V-19 | — | U-1 | A | A |
| Example 20 | V-20 | — | U-1 | A | A |
| Example 21 | V-21 | — | U-1 | A | A |
| Example 22 | V-22 | — | U-1 | A | A |
| Example 23 | V-23 | — | U-2 | A | A |
| Example 24 | V-24 | — | U-3 | A | A |
| Example 25 | V-25 | — | U-4 | A | A |
| Example 26 | V-26 | L-1 | U-1 | A | B |
| Comparative | R-1 | — | U-1 | C | A |
| Example 1 | | | | | |
| Comparative | R-2 | — | U-1 | C | A |
| Example 2 | | | | | |
| Comparative | R-3 | — | U-1 | C | A |
| Example 3 | | | | | |

In addition, regarding the silicon wafer with the pattern according to each of Examples subjected to the evaluations, each silicon wafer was etched using this pattern as an etching mask, and a semiconductor element was produced using this silicon wafer. There was no problem in the performance of any of the semiconductor elements.

### EXPLANATION OF REFERENCES

1: Main chain of polymer

2: Ring structure derived from compound C

What is claimed is:

1. A curable composition for imprinting, comprising:
a compound C represented by Formula (C1); and
a radical polymerization initiator, 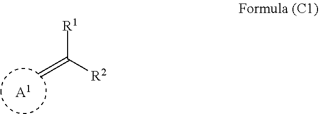
in Formula (C1), A¹ represents a ring structure having 4 to 20 ring members, and R¹ and R² each independently represent a hydrogen atom or a substituent, and
A¹ may have one or more substituents on the ring structure, and in a case where A¹ has a plurality of substituents, the respective substituents may be bonded to each other to form a ring.

2. The curable composition according to claim 1,
wherein the compound C includes a compound represented by Formula (C2), 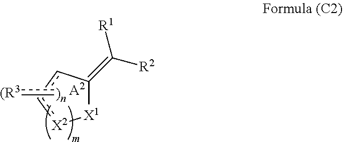
in Formula (C2), A² represents a ring structure having (m+4) ring members, R¹ and R² each independently represent a hydrogen atom or a substituent, R³'s each independently represent an oxygen atom, a sulfur atom, or a substituent, X¹ and X² each independently represent a carbon atom, a nitrogen atom, an oxygen atom, or a sulfur atom, m represents an integer of 0 to 3, n represents an integer of 0 to 12, the respective R³'s may be bonded to each other to form a ring, and a double line consisting of a solid line and a dotted line represents a single bond or a double bond.

3. The curable composition according to claim 1,
wherein the compound C includes a compound represented by Formula (C3), 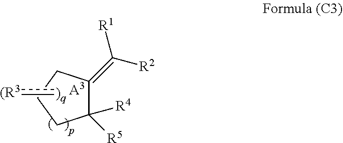
in Formula (C3), A³ represents a ring structure having (p+4) ring members, R¹, R², R⁴, and R⁵ each independently represent a hydrogen atom or a substituent, R³'s each independently represent an oxygen atom, a sulfur atom, or a substituent, p represents an integer of 0 to 3, q represents an integer of 0 to 12, R³, R⁴, and R⁵ may be bonded to each other to form a ring, and a double line consisting of a solid line and a dotted line represents a single bond or a double bond.

4. The curable composition according to claim 3,
wherein at least one of R⁴ or R⁵ is an alkyl group.

5. The curable composition according to claim 2,
wherein at least two of R³'s in Formula (C2) or at least two of R³, R⁴, or R⁵ in Formula (C3) are bonded to each other to form a ring.

6. The curable composition according to claim 1,
wherein at least one of R¹ or R² is a hydrogen atom.

7. The curable composition according to claim 1,
wherein a content of the compound C is 0.01% to 10% by mass with respect to an amount of a total solid content.

8. The curable composition according to claim 1, further comprising a polymerizable compound.

9. The curable composition according to claim 8,
wherein the polymerizable compound includes a polyfunctional polymerizable compound.

10. The curable composition according to claim 8,
wherein the polymerizable compound includes a polymerizable compound having an ethylenically unsaturated bond.

11. The curable composition according to claim 8,
wherein a content of the compound C is 0.01% to 20% by mass with respect to the total polymerizable compound.

12. The curable composition according to claim 1,
wherein the radical polymerization initiator includes a photoradical polymerization initiator.

13. The curable composition according to claim 1, further comprising a release agent.

14. The curable composition according to claim 13,
wherein the release agent has a polyalkylene glycol structure.

15. The curable composition according to claim 1, which is used for imprinting.

16. A kit comprising:
the curable composition according to claim 1; and
a composition for forming an underlayer film, which is for forming an underlayer film for imprinting.

17. A pattern producing method comprising applying the curable composition according to claim 1 onto a substrate or a mold and irradiating the curable composition with light in a state of being sandwiched between the mold and the substrate.

18. A method for manufacturing a semiconductor element, comprising the producing method according to claim 17 as a step.

19. The method for manufacturing a semiconductor element according to claim 18, further comprising performing etching using a pattern as a mask.
